(19) United States
(12) Patent Application Publication
(10) Pub. No.: US 2025/0253151 A1
(43) Pub. Date: Aug. 7, 2025

(54) METHOD FOR FABRICATING A SEMICONDUCTOR DEVICE

(71) Applicant: SAMSUNG ELECTRONICS CO., LTD., Suwon-si (KR)

(72) Inventors: Jong Soon PARK, Suwon-si (KR); Hyon Wook Ra, Suwon-si (KR); Sang Duk Park, Suwon-si (KR); Keun Hee Bai, Suwon-si (KR); Sug Hyun Sung, Suwon-si (KR); Seong Ho Son, Suwon-si (KR)

(73) Assignee: SAMSUNG ELECTRONICS CO., LTD., Suwon-si (KR)

(21) Appl. No.: 18/830,110

(22) Filed: Sep. 10, 2024

(30) Foreign Application Priority Data
Feb. 2, 2024 (KR) 10-2024-0016491

(51) Int. Cl. H01L 21/033; H01L 21/768; H01L 29/06; H01L 29/423; H01L 29/66

(52) U.S. Cl. CPC H01L 21/0334; H01L 21/76841; H10D 30/014; H10D 30/6735; H10D 62/121; H10D 64/017

(57) ABSTRACT

A method of fabricating a semiconductor device includes providing a substrate including a first region and a second region adjacent to the first region, sequentially forming, on an upper surface of the substrate, a lower mask material layer, a first mid mask material layer, a second mid mask material layer and a first upper mask material layer, forming a first mask pattern and a second mask pattern spaced apart from each other in a first horizontal direction on an upper surface of the first upper mask material layer on the first region of the substrate, forming a third mask pattern and a fourth mask pattern spaced apart from each other in the first horizontal direction on the upper surface of the first upper mask material layer on the second region of the substrate, forming a second upper mask material layer covering the first mask pattern, the second mask pattern, the third mask pattern, and the fourth mask pattern on the upper surface of the first upper mask material layer.

### CROSS-REFERENCE TO RELATED APPLICATION

This application is based on and claims priority to Korean Patent Application No. 10-2024-0016491, filed on Feb. 2, 2024, in the Korean Intellectual Property Office, the disclosure of which is herein incorporated by reference herein in its entirety.

### BACKGROUND

Example embodiments of the disclosure relate to a method for fabricating a semiconductor device.

A multi-gate transistor in which a fin-shaped or nanowire-shaped silicon body is formed on a substrate and a gate is formed on a surface of the silicon body has been proposed as a scaling technology for increasing density of an integrated circuit device.

Since such a multi-gate transistor utilizes a three-dimensional channel, scaling may be easily performed. Further, even if a gate length of the multi-gate transistor is not increased, the current control capability may be improved. Furthermore, a short channel effect (SCE) in which potential of a channel region is influenced by a drain voltage may be effectively suppressed.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a method for fabricating a semiconductor device that may prevent an occurrence of process defect of a mask pattern in the process of etching a substrate to form an active pattern.

Additional aspects will be set forth in part in the description which follows and, in part, will be apparent from the description, or may be learned by practice of the presented embodiments.

According to an aspect of an example embodiment, a method of fabricating a semiconductor device may include providing a substrate including a first region and a second region adjacent to the first region, sequentially forming, on an upper surface of the substrate, a lower mask material layer, a first mid mask material layer, a second mid mask material layer and a first upper mask material layer, forming a first mask pattern and a second mask pattern spaced apart from each other in a first horizontal direction on an upper surface of the first upper mask material layer on the first region of the substrate, forming a third mask pattern and a fourth mask pattern spaced apart from each other in the first horizontal direction on the upper surface of the first upper mask material layer on the second region of the substrate, forming a second upper mask material layer covering the first mask pattern, the second mask pattern, the third mask pattern, and the fourth mask pattern on the upper surface of the first upper mask material layer, etching the second upper mask material layer on the second region of the substrate, forming a first upper mask pattern and a second upper mask pattern respectively below the third mask pattern and the fourth mask pattern by etching a portion of the first upper mask material layer on the second region of the substrate, forming a first liner pattern on a side wall of each of the first upper mask material layer and the second upper mask material layer on a boundary between the first region of the substrate and the second region of the substrate, where the first liner pattern does not contact the first mask pattern and the second mask pattern, forming a first liner layer surrounding the side wall of the first upper mask pattern, forming a second liner layer surrounding the side wall of the second upper mask pattern, forming a third upper mask pattern and a fourth upper mask pattern respectively below the first mask pattern and the second mask pattern by etching a portion of the first upper mask material layer, etching the first upper mask pattern and the second upper mask pattern, forming a second liner pattern and a third liner pattern spaced apart in the first horizontal direction by etching a portion of the first liner layer, forming a fourth liner pattern and a fifth liner pattern spaced apart in the first horizontal direction by etching a portion of the second liner layer, forming a first lower mask pattern, a second lower mask pattern, a third lower mask pattern, a fourth lower mask pattern, a fifth lower mask pattern, a sixth lower mask pattern, and a seventh lower mask pattern sequentially spaced apart in the first horizontal direction and respectively below the third upper mask pattern, the fourth upper mask pattern, the first liner pattern, the second liner pattern, the third liner pattern, the fourth liner pattern, and the fifth liner pattern, by etching the second mid mask material layer, the first mid mask material layer, and the lower mask material layer, the first lower mask pattern and the second lower mask pattern being formed on the first region of the substrate, the third lower mask pattern being formed on the boundary between the first region of the substrate and the second region of the substrate, and the fourth lower mask pattern, the fifth lower mask pattern, the sixth lower mask pattern, and the seventh lower mask pattern being formed on the second region of the substrate, and forming a first active pattern, a second active pattern, a dummy active pattern, a third active pattern, a fourth active pattern, a fifth active pattern, and a sixth active pattern sequentially spaced apart in the first horizontal direction and respectively below the first lower mask pattern, the second lower mask pattern, the third lower mask pattern, the fourth lower mask pattern, the fifth lower mask pattern, the sixth lower mask pattern, and the seventh lower mask pattern, by etching the substrate.

According to an aspect of an example embodiment, a method of fabricating a semiconductor device may include providing a substrate including a first region and a second region adjacent to the first region, forming a stacked structure in which a first semiconductor layer and a second semiconductor layer are alternately stacked on an upper surface of the substrate, sequentially forming, on an upper surface of the stacked structure, a lower mask material layer, a first mid mask material layer, a second mid mask material layer and a first upper mask material layer on an upper surface of the stacked structure, sequentially forming, on an upper surface of the stacked structure, a lower mask material layer, a first mid mask material layer, a second mid mask material layer and a first upper mask material layer on an upper surface of the stacked structure, forming a third mask pattern and a fourth mask pattern spaced apart from each other in the first horizontal direction on the upper surface of the first upper mask material layer on the second region of the substrate, forming a first upper mask pattern and a second upper mask pattern respectively below the third mask pattern and the fourth mask pattern by etching a portion of the first upper mask material layer on the second region of the substrate, forming a first liner pattern on a side wall of the first upper mask material layer on a boundary between the first region of the substrate and the second region of the substrate, where the first liner pattern does not contact the first mask pattern and the second mask pattern, forming a first liner layer surrounding the side wall of the first upper mask pattern, forming a second liner layer surrounding the side wall of the second upper mask pattern, where an upper surface of the first liner pattern is higher than an upper surface of the first liner layer and an upper surface of the second liner layer, forming a third upper mask pattern and a fourth upper mask pattern respectively below the first mask pattern and the second mask pattern by etching a portion of the first upper mask material layer on the first region of the substrate, etching the first upper mask pattern and the second upper mask pattern, forming a second liner pattern and a third liner pattern spaced apart in the first horizontal direction by etching a portion of the first liner layer, forming a fourth liner pattern and a fifth liner pattern spaced apart in the first horizontal direction by etching a portion of the second liner layer, forming a first lower mask pattern, a second lower mask pattern, a third lower mask pattern, a fourth lower mask pattern, a fifth lower mask pattern, a sixth lower mask pattern, and a seventh lower mask pattern sequentially spaced apart in the first horizontal direction and respectively below the third upper mask pattern, the fourth upper mask pattern, the first liner pattern, the second liner pattern, the third liner pattern, the fourth liner pattern, and the fifth liner pattern, by etching the second mid mask material layer, the first mid mask material layer, and the lower mask material layer, the first lower mask pattern and the second lower mask pattern being formed on the first region of the substrate, the third lower mask pattern being formed on the boundary between the first region of the substrate and the second region of the substrate, and the fourth lower mask pattern, the fifth lower mask pattern, the sixth lower mask pattern, and the seventh lower mask pattern being formed on the second region of the substrate, and forming a first active pattern, a second active pattern, a dummy active pattern, a third active pattern, a fourth active pattern, a fifth active pattern, and a sixth active pattern sequentially spaced apart in the first horizontal direction and respectively below the first lower mask pattern, the second lower mask pattern, the third lower mask pattern, the fourth lower mask pattern, the fifth lower mask pattern, the sixth lower mask pattern, and the seventh lower mask pattern, by etching the substrate.

According to an aspect of an example embodiment, a method of fabricating a semiconductor device may include providing a substrate including a first region and a second region adjacent to the first region, forming a stacked structure in which a first semiconductor layer and a second semiconductor layer are alternately stacked on an upper surface of the substrate, sequentially forming, on an upper surface of the substrate, a lower mask material layer, a first mid mask material layer, a second mid mask material layer and a first upper mask material layer, forming a first mask pattern and a second mask pattern spaced apart from each other in a first horizontal direction on an upper surface of the first upper mask material layer on the first region of the substrate, forming a third mask pattern and a fourth mask pattern spaced apart from each other in the first horizontal direction on the upper surface of the first upper mask material layer on the second region of the substrate, forming a second upper mask material layer covering the first mask pattern, the second mask pattern, the third mask pattern, and the fourth mask pattern on the upper surface of the first upper mask material layer, etching the second upper mask material layer on the second region of the substrate, forming a first upper mask pattern and a second upper mask pattern respectively below the third mask pattern and the fourth mask pattern by etching a portion of the first upper mask material layer on the second region of the substrate, forming a first liner pattern on a side wall of each of the first upper mask material layer and the second upper mask material layer on a boundary between the first region of the substrate and the second region of the substrate, where the first liner pattern does not contact the first mask pattern and the second mask pattern, forming a first liner layer surrounding the side wall of the first upper mask pattern, forming a second liner layer surrounding the side wall of the second upper mask pattern, where an upper surface of the first liner pattern is higher than an upper surface of the first liner layer and an upper surface of the second liner layer, forming a third upper mask pattern and a fourth upper mask pattern respectively below the first mask pattern and the second mask pattern by etching a portion of the first upper mask material layer on the first region of the substrate, etching the first upper mask pattern and the second upper mask pattern, forming a second liner pattern and a third liner pattern spaced apart in the first horizontal direction by etching a portion of the first liner layer, forming a fourth liner pattern and a fifth liner pattern spaced apart in the first horizontal direction by etching a portion of the second liner layer, forming a first lower mask pattern, a second lower mask pattern, a third lower mask pattern, a fourth lower mask pattern, a fifth lower mask pattern, a sixth lower mask pattern, and a seventh lower mask pattern sequentially spaced apart in the first horizontal direction respectively below the third upper mask pattern, the fourth upper mask pattern, the first liner pattern, the second liner pattern, the third liner pattern, the fourth liner pattern, and the fifth liner pattern, by etching the second mid mask material layer, the first mid mask material layer, and the lower mask material layer, the first lower mask pattern and the second lower mask pattern being formed on the first region of the substrate, the third lower mask pattern being formed on the boundary between the first region of the substrate and the second region of the substrate, and the fourth lower mask pattern, the fifth lower mask pattern, the sixth lower mask pattern, and the seventh lower mask pattern being formed on the second region of the substrate, forming a first active pattern, a second active pattern, a dummy active pattern, a third active pattern, a fourth active pattern, a fifth active pattern, and a sixth active pattern sequentially spaced apart in the first horizontal direction and respectively below the first lower mask pattern, the second lower mask pattern, the third lower mask pattern, the fourth lower mask pattern, the fifth lower mask pattern, the sixth lower mask pattern, and the seventh lower mask pattern, by etching the substrate, a width of the dummy active pattern in the first horizontal direction being equal to a width of each of the third active pattern, the fourth active pattern, the fifth active pattern, and the sixth active pattern in the first horizontal direction, forming a first active pattern, a second active pattern, a dummy active pattern, a third active pattern, a fourth active pattern, a fifth active pattern, and a sixth active pattern sequentially spaced apart in the first horizontal direction and respectively below the first lower mask pattern, the second lower mask pattern, the third lower mask pattern, the fourth lower mask pattern, the fifth lower mask pattern, the sixth lower mask pattern, and the seventh lower mask pattern, by etching the substrate, a width of the dummy active pattern in the first horizontal direction being equal to a width of each of the third active pattern, the fourth active pattern, the fifth active pattern, and the sixth active pattern in the first horizontal direction, etching the dummy gate, forming a gate insulating layer and a gate electrode in a portion in which the dummy gate is etched, and forming a gate cut extending in a vertical direction on the dummy active pattern, the gate cut contacting the dummy active pattern and separating the gate electrode in the first horizontal direction.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram for illustrating a semiconductor device according to one or more embodiments;

FIG. 2 is a diagram in which a partial region of FIG. 1 is enlarged according to one or more embodiments;

FIG. 3 is a cross-sectional view taken along line A-A′ of FIG. 2 according to one or more embodiments;

FIGS. 4 to 27 are diagrams illustrating a method of fabricating a semiconductor device according to one or more embodiments;

FIG. 28 is a diagram illustrating a semiconductor device according to one or more embodiments;

FIG. 29 is a cross-sectional view illustrating a semiconductor device according to one or more embodiments;

FIGS. 30 and 31 are diagrams illustrating a method of fabricating a semiconductor device according to one or more embodiments;

FIG. 32 is a diagram illustrating a semiconductor device according to one or

more embodiments;

FIG. 33 is a cross-sectional view illustrating a semiconductor device according to one or more embodiments; and

FIGS. 34 to 47 are diagrams illustrating a method of fabricating a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Terms such as “surround,” “cover,” etc., may indicate a partial or complete surrounding/covering unless the description and/or context indicates otherwise.

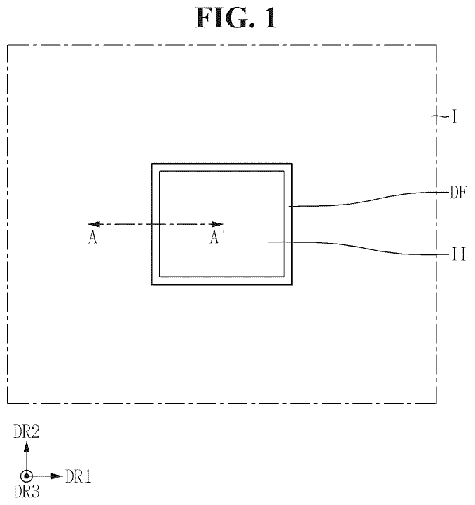

Hereinafter, a semiconductor device according to one or more embodiments of the present disclosure will be described with reference to FIGS. 1 to 3.

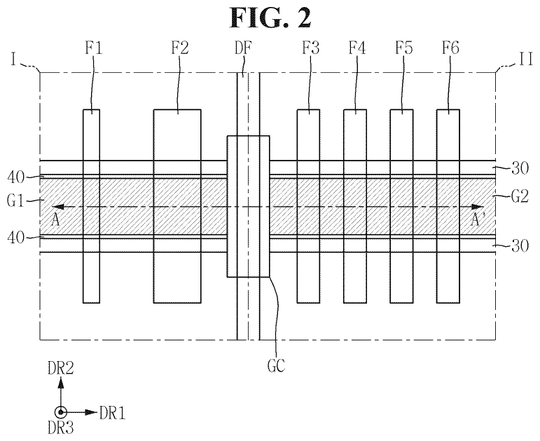

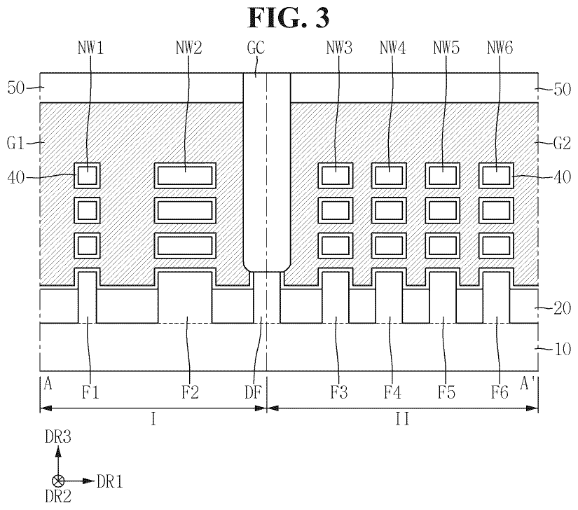

FIG. 1 is a diagram for illustrating a semiconductor device according to one or more embodiments. FIG. 2 is a diagram in which a partial region of FIG. 1 is enlarged according to one or more embodiments. FIG. 3 is a cross-sectional view taken along line A-A′ of FIG. 2 according to one or more embodiments.

Referring to FIGS. 1 to 3, the semiconductor device according to one or more embodiments may include a substrate 10, first to sixth active patterns F1 to F6, a dummy active pattern DF, a field insulating layer 20, first to sixth plurality of nanosheets NW1 to NW6, first and second gate electrodes G1 and G2, a gate spacer 30, a gate insulating layer 40, a capping pattern 50, and a gate cut GC.

The substrate 10 may be a silicon substrate or silicon-on-insulator (SOI). In contrast, the substrate 10 may include silicon germanium, silicon germanium on insulator (SGOI), indium antimonide, lead telluride, indium arsenide, indium phosphide, gallium arsenide or gallium antimonide, but embodiments are not limited thereto.

Hereinafter, each of a first horizontal direction DR1 and a second horizontal direction DR2 may be defined as a direction parallel to an upper surface of the substrate 10. The second horizontal direction DR2 may be defined as a direction different from the first horizontal direction DR1. A vertical direction DR3 may be defined as a direction perpendicular to each of the first horizontal direction DR1 and the second horizontal direction DR2. That is, the vertical direction DR3 may be defined as a direction perpendicular to the upper surface of the substrate 10.

For example, the substrate 10 may include a first region I and a second region II. The second region II may be disposed to be adjacent to the first region I. For example, the first region I may completely surround the second region II on a plane defined by the first horizontal direction DR1 and the second horizontal direction DR2. For example, the first region I may be a region in which a logic transistor is formed, and the second region II may be a region in which a static random access memory (RAM) (SRAM) transistor is formed.

Each of the first to sixth active patterns F1 to F6 may extend in the second horizontal direction DR2 on the upper surface of the substrate 10. Each of the first to sixth active patterns F1 to F6 may protrude from the upper surface of the substrate 10 in the vertical direction DR3. For example, each of the first and second active patterns F1 and F2 may be disposed on the upper surface of the first region I of the substrate 10. The second active pattern F2 may be spaced apart from the first active pattern F1 in the first horizontal direction DR1. Each of third to sixth active patterns F3 to F6 may be disposed on the upper surface of the second region II of the substrate 10. A fourth active pattern F4 may be spaced apart from a third active pattern F3 in the first horizontal direction DR1. A fifth active pattern F5 may be spaced apart from the fourth active pattern F4 in the first horizontal direction DR1. A sixth active pattern F6 may be spaced apart from the fifth active pattern F5 in the first horizontal direction DR1.

For example, the dummy active pattern DF may be disposed between the second active pattern F2 and the third active pattern F3. The dummy active pattern DF may be spaced apart from each of the second active pattern F2 and the third active pattern F3 in the first horizontal direction DR1. The dummy active pattern DF may protrude from the upper surface of the substrate 10 in the vertical direction DR3. For example, the dummy active pattern DF may be disposed on a boundary line (or a boundary area) between the first region I of the substrate 10 and the second region II of the substrate 10. For example, the dummy active pattern DF may have an annular shape on a plane defined by the first horizontal direction DR1 and the second horizontal direction DR2. For example, the upper surface of the dummy active pattern DF may be formed on the same plane as the upper surface of each of the first to sixth active patterns F1 to F6. However, embodiments not limited thereto. In some one or more embodiments, the upper surface of the dummy active pattern DF may be formed to be lower than the upper surface of each of the first to sixth active patterns F1 to F6.

For example, a width of the second active pattern F2 in the first horizontal direction DR1 may be greater than a width of the first active pattern F1 in the first horizontal direction DR1. For example, the widths of each of the third to sixth active patterns F3 to F6 in the first horizontal direction DR1 may be equal to each other. For example, the width of the dummy active pattern DF in the first horizontal direction DR1 may be equal to the width of each of the third to sixth active patterns F3 to F6 in the first horizontal direction DR1. For example, the width of the second active pattern F2 in the first horizontal direction DR1 may be greater than the width DR1 of each of the dummy active pattern DF and the third to sixth active patterns F3 to F6 in the first horizontal direction. For example, the width of the first active pattern F1 in the first horizontal direction DR1 may be smaller than the width of each of the dummy active pattern DF and the third to sixth active patterns F3 to F6 in the first horizontal direction DR1.

For example, pitches in the first horizontal direction DR1 between each of the third to sixth active patterns F3 to F6 may be equal to each other. For example, a pitch in the first horizontal direction DR1 between the first active pattern F1 and the second active pattern F2 may be greater than a pitch in the first horizontal direction DR1 between the third active pattern F3 and the fourth active pattern F4. For example, each of the first to sixth active patterns F1 to F6 and the dummy active pattern DF may include the same material as the substrate 10.

The field insulating layer 20 may be disposed on the upper surface of the substrate 10. The field insulating layer 20 may surround the side walls of each of the first to sixth active patterns F1 to F6 and the dummy active pattern DF. For example, the upper surfaces of each of the first to sixth active patterns F1 to F6 and the dummy active pattern DF may protrude from the upper surface of the field insulating layer 20 in the vertical direction DR3. For example, the dummy active pattern DF may separate the field insulating layer 20 disposed on the first region I of the substrate 10 and the field insulating layer 20 disposed on the second region II of the substrate 10. The field insulating layer 20 may include, for example, an oxide film, a nitride film, an oxynitride film or a combined film thereof.

A first plurality of nanosheets NW1 may be disposed on the first active pattern F1. A second plurality of nanosheets NW2 may be disposed on the second active pattern F2. A third plurality of nanosheets NW3 may be disposed on the third active pattern F3. A fourth plurality of nanosheets NW4 may be disposed on the fourth active pattern F4. A fifth plurality of nanosheets NW5 may be disposed on the fifth active pattern F5. A sixth plurality of nanosheets NW6 may be disposed on the sixth active pattern F6. The first to sixth plurality of nanosheets NW1 to NW6 may be sequentially spaced apart in the first horizontal direction DR1.

Each of the first to sixth plurality of nanosheets NW1 to NW6 may include a plurality of nanosheets stacked and spaced apart from each other in the vertical direction DR3. In FIG. 3, although each of the first to sixth nanosheets NW1 to NW6 is shown as including three nanosheets stacked and spaced apart from each other in the vertical direction DR3, this is for convenience of explanation, and embodiments are not limited thereto. In some one or more embodiments, each of the first to sixth plurality of nanosheets NW1 to NW6 may include four or more nanosheets stacked and spaced apart from each other in the vertical direction DR3. For example, each of the first to sixth nanosheets NW1 to NW6 may include silicon (Si). However, embodiments are not limited thereto. In some one or more embodiments, each of the first to sixth plurality of nanosheets NW1 to NW6 may include silicon germanium (SiGe).

A first gate electrode G1 may extend in the first horizontal direction DR1 on the field insulating layer 20 and the first and second active patterns F1 and F2. The first gate electrode G1 may surround each of the first and second plurality of nanosheets NW1 and NW2. A second gate electrode G2 may extend in the first horizontal direction DR1 on the field insulating layer 20 and the third to sixth active patterns F3 to F6. The second gate electrode G2 may be spaced apart from the first gate electrode G1 in the first horizontal direction DR1. The second gate electrode G2 may surround each of the third to sixth plurality of nanosheets NW3 to NW6.

Each of the first and second gate electrodes G1 and G2 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAIC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. Each of the first and second gate electrodes G1 and G2 may include a conductive metal oxide, a conductive metal oxynitride, and the like, and may include an oxidized form of the aforementioned materials.

The gate spacer 30 may be disposed on side walls of the first and second gate electrodes G1 and G2 in the second horizontal direction DR2. The gate spacer 30 may extend in the first horizontal direction DR1. For example, the gate spacer 30 disposed on side walls of the second gate electrode G2 may be spaced apart from the gate spacer 30 disposed on side walls of the first gate electrode G1 in the first horizontal direction DR1. The gate spacer 30 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. However, embodiments are not limited thereto.

The gate insulating layer 40 may be disposed between each of the first and second gate electrodes G1 and G2 and the field insulating layer 20. The gate insulating layer 40 may be disposed between each of the first and second gate electrodes G1 and G2 and the gate spacer 30. The gate insulating layer 40 may be disposed between the first gate electrode G1 and each of the first and second active patterns F1 and F2. The gate insulating layer 40 may be disposed between the first gate electrode G1 and the dummy active pattern DF. The gate insulating layer 40 may be disposed between the first gate electrode G1 and each of the first and second plurality of nanosheets NW1 and NW2. The gate insulating layer 40 may be disposed between the second gate electrode G2 and each of the third to sixth active patterns F3 to F6. The gate insulating layer 40 may be disposed between the second gate electrode G2 and the dummy active pattern DF. The gate insulating layer 40 may be disposed between the second gate electrode G2 and each of the third to sixth nanosheets NW3 to NW6.

The gate insulating layer 40 may include at least one of silicon oxide, silicon oxynitride, silicon nitride and a high dielectric constant material having a higher dielectric constant than silicon oxide. The high dielectric constant material may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

A semiconductor device according to some one or more embodiments may include a negative capacitance (NC) field effect transistor (FET) that uses a negative capacitor. For example, the gate insulating layer 40 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. The thickness of the ferroelectric material film may be, for example, but not limited to, 0.5 to 10 nm. Since a critical thickness that exhibits the ferroelectric properties may vary for each ferroelectric material, the thickness of the ferroelectric material film may vary depending on the ferroelectric material.

As an example, the gate insulating layer 40 may include one ferroelectric material film. As another example, the gate insulating layer 40 may include a plurality of ferroelectric material films spaced apart from each other. The gate insulating layer 40 may have a stacked film structure in which the plurality of ferroelectric material films and the plurality of paraelectric material films are alternately stacked.

The capping pattern 50 may extend in the first horizontal direction DR1 on each of the gate spacer 30, the gate insulating layer 40, the first gate electrode G1, and the second gate electrode G2. For example, the capping pattern 50 disposed on the second gate electrode G2 may be spaced apart from the capping pattern 50 disposed on the second gate electrode G2 in the first horizontal direction DR1. The capping pattern 50 may include, for example, at least one of silicon nitride (SiN), silicon oxynitride (SiON), silicon oxide (SiO₂), silicon carbonitride (SiCN), silicon oxycarbonitride (SiOCN), and combinations thereof. However, embodiments are not limited thereto.

The gate cut GC may be disposed on the boundary line (or boundary area) between the first region I of the substrate 10 and the second region II of the substrate. The gate cut GC may be disposed between the second plurality of nanosheets NW2 and the third plurality of nanosheets NW3. The gate cut GC may be spaced apart from each of the second plurality of nanosheets NW2 and the third plurality of nanosheets NW3 in the first horizontal direction DR1. The gate cut GC may be disposed on the upper surface of the dummy active pattern DF. The gate cut GC may extend in the vertical direction DR3 from the upper surface of the dummy active pattern DF. The gate cut GC may separate the first gate electrode G1 and the second gate electrode G2 in the first horizontal direction DR1.

For example, the lower surface of the gate cut GC may contact the upper surface of the dummy active pattern DF. For example, the gate cut GC may contact each of the first and second gate electrodes G1 and G2 and the capping pattern 50. For example, the upper surface of the gate cut GC may be formed on the same plane as the upper surface of the capping pattern 50. However, embodiments are not limited thereto. The gate cut GC may include, for example, one of silicon nitride (SiN), silicon oxynitride (SiON), silicon oxide (SiO₂), silicon oxycarbonitride (SiOCN) and combinations thereof. However, the present disclosure is not limited thereto.

Hereinafter, a method for fabricating the semiconductor device according to one or more embodiments of the present disclosure will be described with reference to FIGS. 1 to 27.

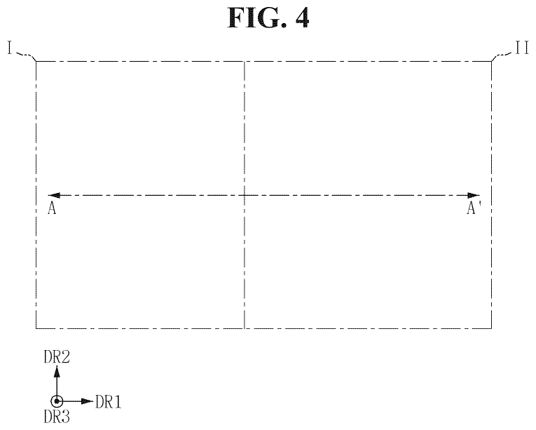

FIGS. 4 to 27 are diagrams illustrating a method of fabricating a semiconductor device according to one or more embodiments.

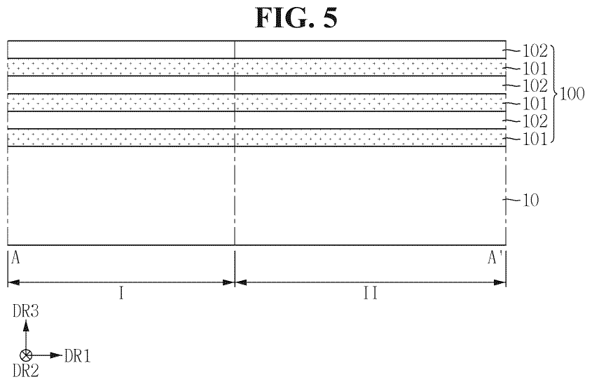

Referring to FIGS. 4 and 5, the substrate 10 that includes the first region I and the second region II adjacent to the first region I may be provided. For example, the first region I may completely surround the second region II on the plane defined by the first horizontal direction DR1 and the second horizontal direction DR2.

Subsequently, the stacked structure 100 may be formed on the upper surface of the substrate 10. The stacked structure 100 may include a first semiconductor layer 101 and a second semiconductor layer 102 that are alternately stacked on the upper surface of the substrate 10. For example, the first semiconductor layer 101 may be formed at the lowermost portion of the stacked structure 100, and the second semiconductor layer 102 may be formed at the uppermost portion of the stacked structure 100. However, embodiments are not limited thereto. In one or more embodiments, the first semiconductor layer 101 may also be formed at the uppermost portion of the stacked structure 100. The first semiconductor layer 101 may include, for example, silicon germanium (SiGe). The second semiconductor layer 102 may include, for example, silicon (Si).

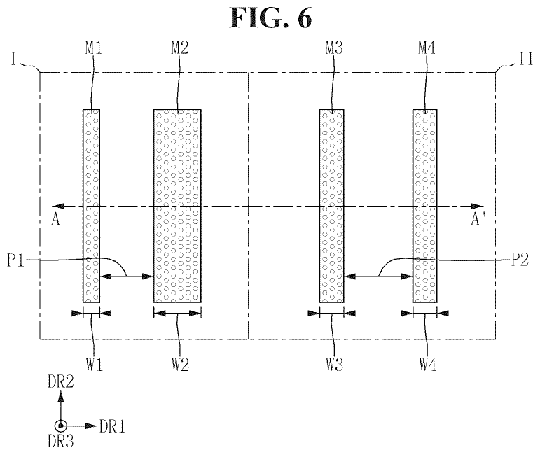

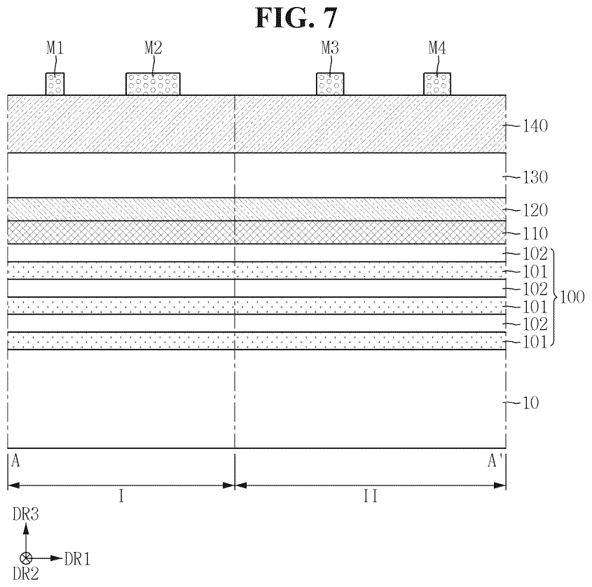

Referring to FIGS. 6 and 7, a lower mask material layer 110, a first mid mask material layer 120, a second mid mask material layer 130, and a first upper mask material layer 140 may be sequentially formed on the upper surface of the stacked structure 100. For example, the lower mask material layer 110 may contact the upper surface of the stacked structure 100. The first mid mask material layer 120 may contact the upper surface of the lower mask material layer 110. The second mid mask material layer 130 may contact the upper surface of the first mid mask material layer 120. The first upper mask material layer 140 may contact the upper surface of the second mid mask material layer 130.

For example, each of the lower mask material layer 110, the first mid mask material layer 120, the second mid mask material layer 130, and the first upper mask material layer 140 may include different materials from each other. For example, the lower mask material layer 110 may include silicon nitride (SiN). In one or more embodiments, the lower mask material layer 110 may include silicon oxynitride (SiON). For example, the first mid mask material layer 120 may include TEOS (TetraEthylOthoSilicate). In one or more embodiments, the first mid mask material layer 120 may include silicon oxide (SiO₂). For example, the second mid mask material layer 130 may include polysilicon. In one or more embodiments, the second mid mask material layer 130 may include polycrystalline silicon. For example, the first upper mask material layer 140 may include an amorphous carbon layer (ACL).

Subsequently, first to fourth mask patterns M1 to M4 may be formed on the upper surface of the first upper mask material layer 140. Each of the first to fourth mask patterns M1 to M4 may extend in the second horizontal direction DR2. For example, each of the first and second mask patterns M1 and M2 may be formed on the first region I of the substrate 10. The second mask pattern M2 may be spaced apart from the first mask pattern M1 in the first horizontal direction DR1. For example, each of the third and fourth mask patterns M3 and M4 may be formed on the second region II of the substrate 10. The third mask pattern M3 may be spaced apart from the second mask pattern M2 in the first horizontal direction DR1. The fourth mask pattern M4 may be spaced apart from the third mask pattern M3 in the first horizontal direction DR1.

For example, a width W2 of the second mask pattern M2 in the first horizontal direction DR1 may be greater than a width W1 of the first mask pattern M1 in the first horizontal direction DR1. For example, the width W3 of the third mask pattern M3 in the first horizontal direction DR1 may be equal to a width W4 of the fourth mask pattern M4 in the first horizontal direction DR1. For example, the width W2 of the second mask pattern M2 in the first horizontal direction DR1 may be greater than the width W3 of the third mask pattern M3 in the first horizontal direction DR1 and the width W4 of the fourth mask pattern M4 in the first horizontal direction DR1. For example, the width W1 of the first mask pattern M1 in the first horizontal direction DR1 may be smaller than each of the width W3 of the third mask pattern M3 in the first horizontal direction DR1 and the width W4 of the fourth mask pattern M4 in the first horizontal direction DR1.

For example, a pitch P1 in the first horizontal direction DR1 between the first mask pattern M1 and the second mask pattern M2 may be smaller than a pitch P2 between the third mask pattern M3 and the fourth mask pattern M4 in the first horizontal direction DR1. Each of the first to fourth mask patterns M1 to M4 may include a material having an etching selectivity with the first upper mask material layer 140. For example, each of the first to fourth mask patterns M1 to M4 may include silicon oxynitride (SiON). In one or more embodiments, each of the first to fourth mask patterns M1 to M4 may include silicon nitride (SiN).

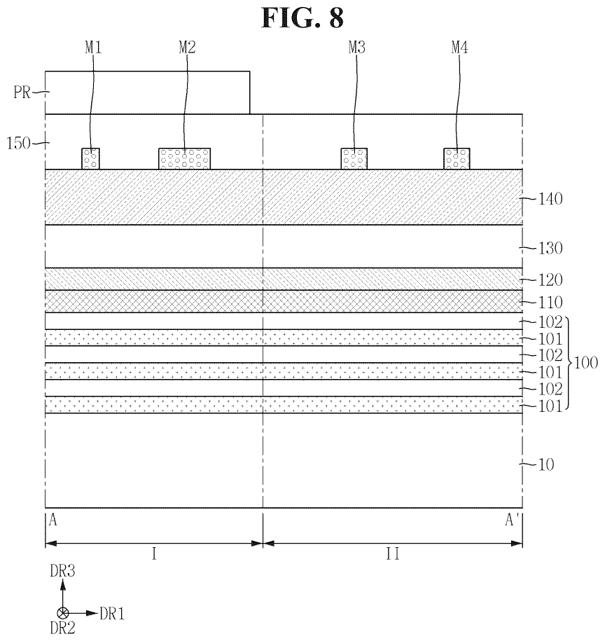

Referring to FIG. 8, a second upper mask material layer 150 may be formed on the upper surface of the first upper mask material layer 140. The second upper mask material layer 150 may cover each of the first to fourth mask patterns M1 to M4. That is, the second upper mask material layer 150 may contact the side walls and upper surfaces of each of the first to fourth mask patterns M1 to M4. For example, the second upper mask material layer 150 may include spin-on hardmask (SOH).

Subsequently, a photoresist pattern PR may be formed on the upper surface of the second upper mask material layer 150 on the first region I of the substrate 10. For example, the photoresist pattern PR may include photoresist. For example, the photoresist pattern PR may expose the upper surface of the second upper mask material layer 150 on the second region II of the substrate 10. Further, the photoresist pattern PR may expose a portion of the upper surface of the second upper mask material layer 150 on the first region I of the substrate 10 adjacent to the boundary line (or boundary area) between the first region I of the substrate 10 and the second region II of the substrate 10.

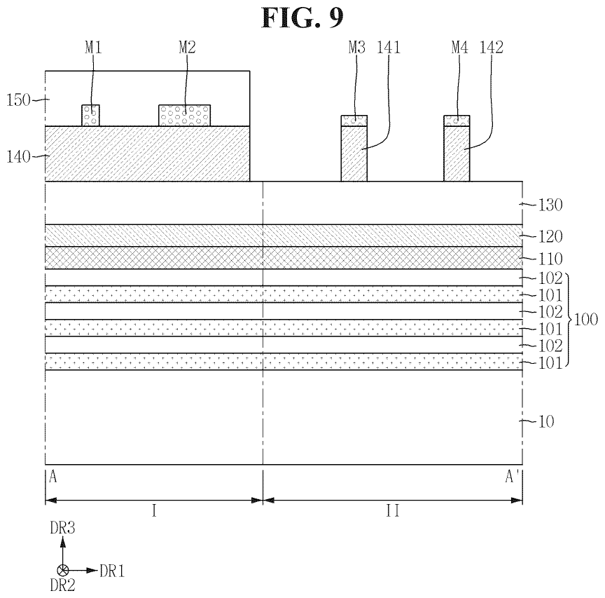

Referring to FIG. 9, a portion of the second upper mask material layer 150 on the second region II of the substrate 10 may be etched, by using the photoresist pattern PR as a mask. Also, the second upper mask material layer 150 on the first region I of the substrate 10 adjacent to the boundary line (or boundary area) between the first region I of the substrate 10 and the second region II of the substrate 10 may be etched, by using the photoresist pattern PR as a mask. Subsequently, a portion of the first upper mask material layer 140 may be etched, by using the remaining second upper mask material layer 150 and each of the third and fourth mask patterns M3 and M4 as masks. For example, a process of etching a portion of the second upper mask material layer 150 and a process of etching a portion of the first upper mask material layer 140 may be performed through the same process.

For example, while a portion of the first upper mask material layer 140 is being etched, a portion of the upper portions of each of the third and fourth mask patterns M3 and M4 may also be etched. After the etching process for a portion of the first upper mask material layer 140 is completed, a portion of the first upper mask material layer 140 remaining under the third mask pattern M3 may be defined as a first upper mask pattern 141, and the other portion of the first upper mask material layer 140 remaining under the fourth mask pattern M4 may be defined as a second upper mask pattern 142.

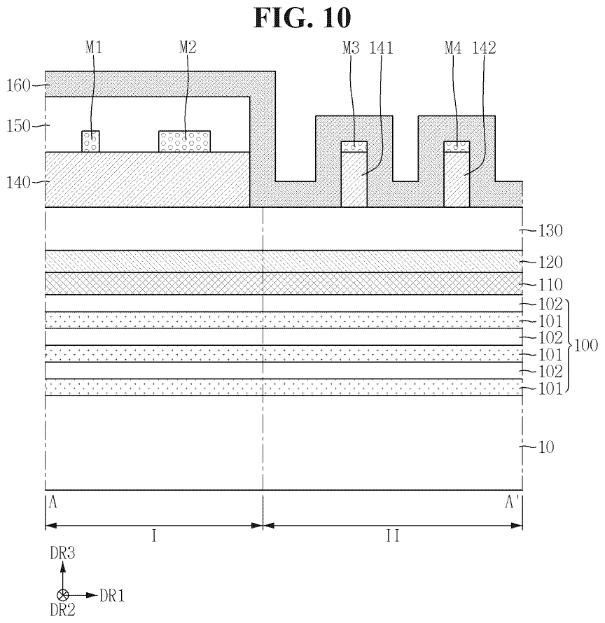

Referring to FIG. 10, a liner layer 160 may be formed on each of the exposed upper surface of the second mid mask material layer 130, the exposed side walls of the first upper mask material layer 140, the exposed side walls and upper surface of the second upper mask material layer 150, the side walls of each of the first and second upper mask patterns 141 and 142, and the side walls and upper surfaces of each of the third and fourth mask patterns M3 and M4. For example, the liner layer 160 may be formed conformally. For example, the liner layer 160 may be spaced apart from each of the first and second mask patterns M1 and M2. That is, the liner layer 160 may not contact each of the first and second mask patterns M1 and M2. The liner layer 160 may include a material different from those of each of the second mid mask material layer 130, the first upper mask material layer 140, the second upper mask material layer 150, and each of the third and fourth mask patterns M3 and M4. For example, the liner layer 160 may include silicon oxide (SiO₂). In one or more embodiments, the liner layer 160 may include silicon nitride (SiN).

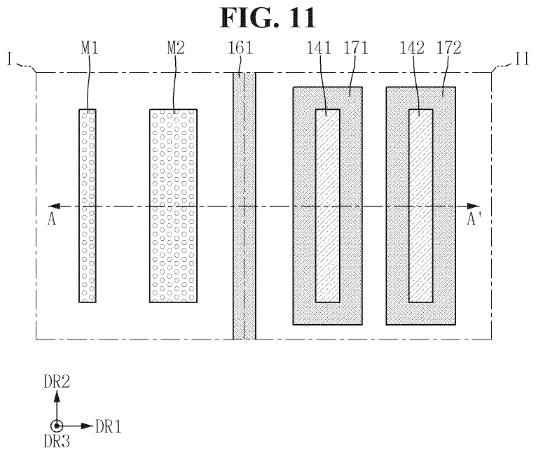

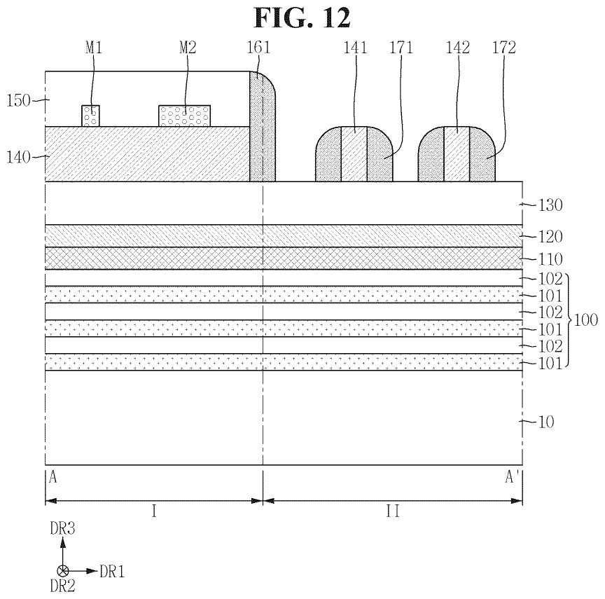

Referring to FIGS. 11 and 12, an etch-back etching process may be performed to etch a portion of the liner layer (160 of FIG. 10). For example, the third and fourth mask patterns M3 and M4 may also be etched through the etch-back etching process. For example, the etch-back etching process may be performed to expose the upper surface of the second upper mask material layer 150, a portion of the upper surface of the second mid mask material layer 130, and the upper surfaces of each of the third and fourth mask patterns M3 and M4.

For example, after the etch-back etching process is completed, the liner layer (160 of FIG. 10) remaining on each of the side walls of the first upper mask material layer 140 and the side walls of the second upper mask material layer 150 may be defined as a first liner pattern 161, on the boundary line (or boundary area) between the first region I of the substrate 10 and the second region II of the substrate 10. In addition, after the etch-back etching process is completed, the liner layer (160 of FIG. 10) remaining on the side wall of the first upper mask pattern 141 may be defined as a first liner layer 171, and the liner layer (160 of FIG. 10) remaining on the side wall of the second upper mask pattern 142 may be defined as a second liner layer 172.

For example, the first liner pattern 161 may be spaced apart from each of the first and second mask patterns M1 and M2. That is, the first liner pattern 161 may not contact each of the first and second mask patterns M1 and M2. For example, after the etch-back etching process is completed, the upper surface of the second mid mask material layer 130 may be exposed between the first liner pattern 161 and the first liner layer 171. Further, after the etch-back etching process is completed, the upper surface of the second mid mask material layer 130 may be exposed between the first liner layer 171 and the second liner layer 172.

For example, the first liner layer 171 may completely surround the side walls of the first upper mask pattern 141. Also, the second liner layer 172 may completely surround the side walls of the second upper mask pattern 142. For example, the upper surface of the first liner pattern 161 may be formed to be higher than each of the upper surface of the first liner layer 171 and the upper surface of the second liner layer 172. For example, the upper surface of the first liner pattern 161 may be formed to be higher than each of the upper surface of the first mask pattern M1 and the upper surface of the second mask pattern M2. For example, each of the upper surface of the first liner layer 171 and the upper surface of the second liner layer 172 may be formed to be lower than each of the upper surface of the first mask pattern M1 and the upper surface of the second mask pattern M2.

For example, the first liner pattern 161 may have an annular shape on the plane defined by the first horizontal direction DR1 and the second horizontal direction DR2. For example, the shape of the first liner pattern 161 may be the same as the shape of the dummy active pattern DF shown in FIG. 1, on the plane defined by the first horizontal direction DR1 and the second horizontal direction DR2.

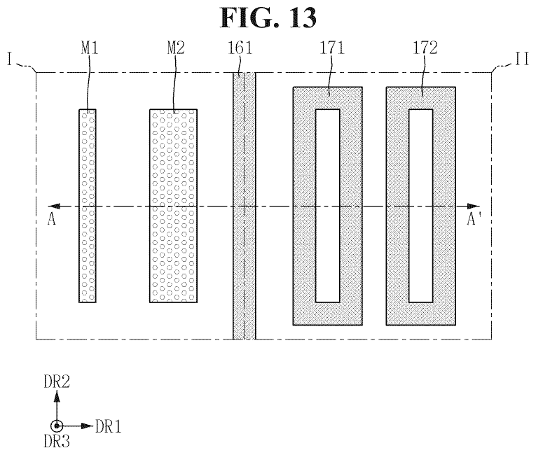

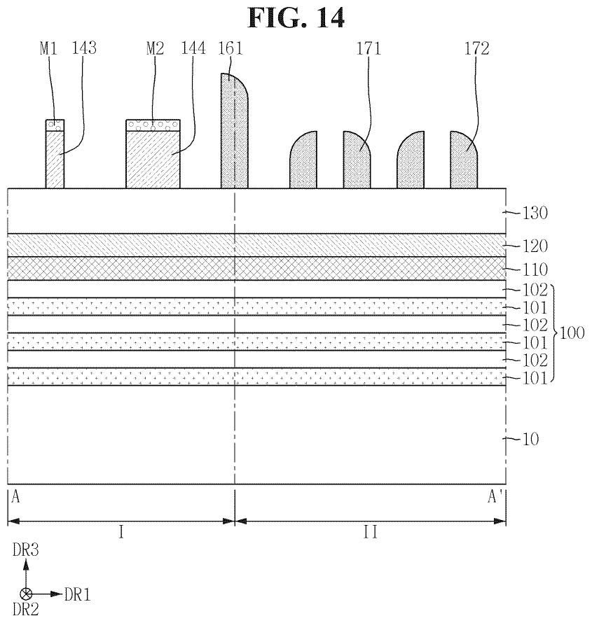

Referring to FIGS. 13 and 14, the second upper mask material layer (150 of FIG. 12) may be etched. A portion of the first upper mask material layer (140 of FIG. 12), the first upper mask pattern (141 of FIG. 12) and the second upper mask pattern (142 of FIG. 12) may then be etched. For example, a portion of the first upper mask material layer (140 of FIG. 12) may be etched, by using each of the first and second mask patterns M1 and M1 as a mask. For example, while a portion of the first upper mask material layer (140 of FIG. 12) is being etched, a portion of the upper portion of each of the first and second mask patterns M1 and M2 may also be etched.

For example, after the etching process for a portion of the first upper mask material layer (140 of FIG. 12) is completed, a portion of the first upper mask material layer (140 of FIG. 12) remaining under the first mask pattern M1 may be defined as a third upper mask pattern 143, and the other portion of the first upper mask material layer (140 of FIG. 12) remaining under the second mask pattern M2 may be defined as a fourth upper mask pattern 144.

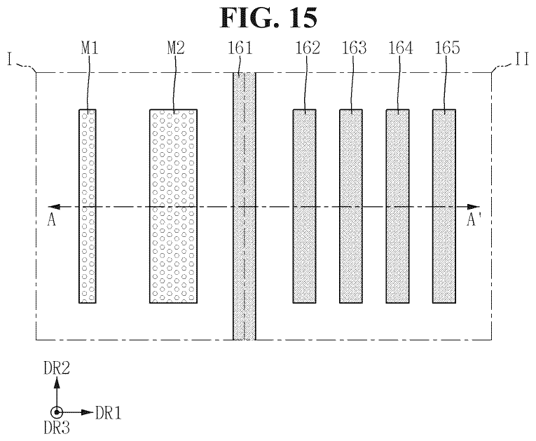

Referring to FIG. 15, both side walls of the first liner layer (171 of FIG. 13) in the second horizontal direction DR2 may be etched. Accordingly, the first liner layer (171 of FIG. 13) may be separated into a second liner pattern 162 and a third liner pattern 163 that are spaced apart from each other in the first horizontal direction DR1. Further, each of both side walls of the second liner layer (172 of FIG. 13) in the second horizontal direction DR2 may be etched. Accordingly, the second liner layer (172 of FIG. 13) may be separated into a fourth liner pattern 164 and a fifth liner pattern 165 that are spaced apart from each other in the first horizontal direction DR1.

The second to fifth liner patterns 162 to 165 may be sequentially spaced apart in the first horizontal direction DR1. For example, the second to fifth liner patterns 162 to 165 may be sequentially spaced apart at equal pitches in the first horizontal direction DR1. Each of the second to fifth liner patterns 162 to 165 may extend in the second horizontal direction DR2. For example, the widths of each of the second to fifth liner patterns 162 to 165 in the first horizontal direction DR1 may be equal to each other. For example, the width of each of the second to fifth liner patterns 162 to 165 in the first horizontal direction DR1 may be equal to the width of the first liner pattern 161 in the first horizontal direction DR1.

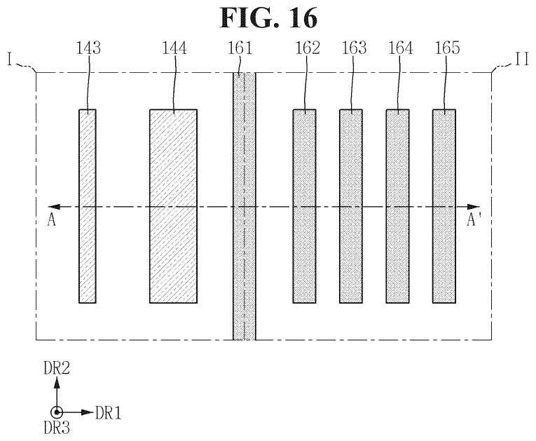

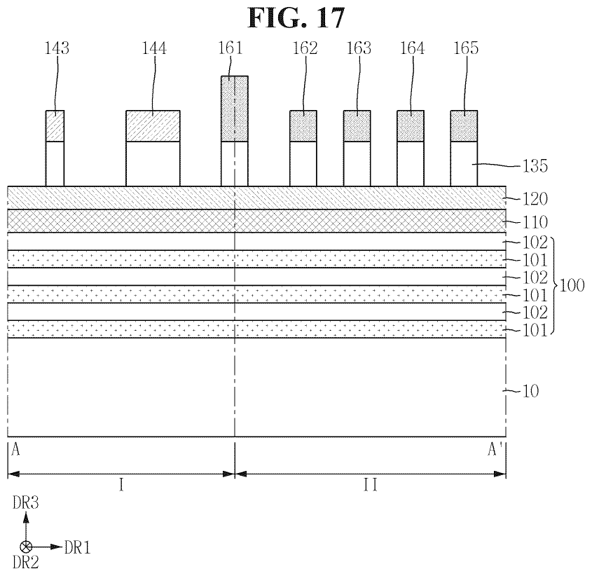

Referring to FIGS. 16 and 17, a portion of the second mid mask material layer (130 of FIG. 14) may be etched to form a mid mask pattern 135, by using each of the first and second mask patterns (M1 and M2 of FIG. 14), the third and fourth upper mask patterns 143 and 144, and the first to fifth liner patterns 161 to 165 as masks. For example, the mid mask pattern 135 may be formed below each of the third and fourth upper mask patterns 143 and 144 and the first to fifth liner patterns 161 to 165.

For example, each of the first and second mask patterns (M1 and M2 of FIG. 14) may be etched, while a portion of the second mid mask material layer (130 of FIG. 14) is being etched. Furthermore, a portion of each of the third and fourth upper mask patterns 143 and 144 and the first to fifth liner patterns 161 to 165 may be etched, while a portion of the second mid mask material layer (130 of FIG. 14) is being etched.

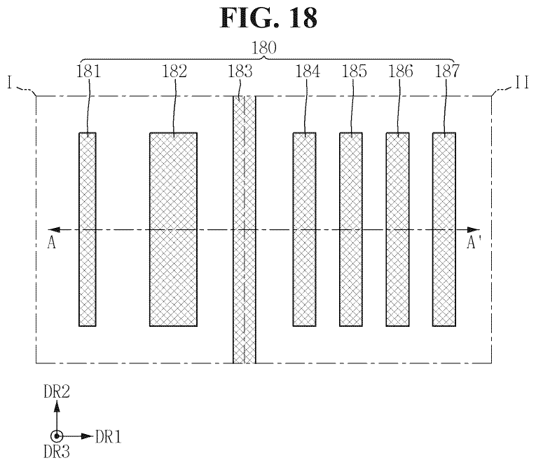

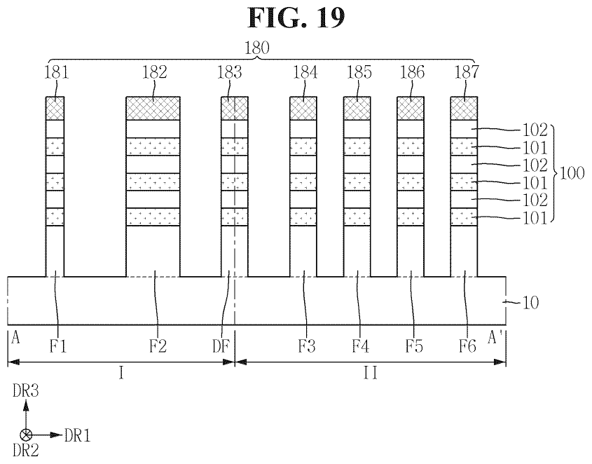

Referring to FIGS. 18 and 19, a portion of the first mid mask material layer (120 of FIG. 17) and the lower mask material layer (110 of FIG. 17) may be etched, by using the third and fourth upper mask patterns (143 and 144 of FIG. 17), the first to fifth liner patterns (161 to 165 of FIG. 17), and the mid mask pattern (135 of FIG. 17) as masks. While such an etching process is being performed, the third and fourth upper mask patterns (143 and 144 of FIG. 17), the first to fifth liner patterns (161 to 165 of FIG. 17), the mid mask pattern (135 of FIG. 17), and the first mid mask material layer (120 of FIG. 17) may be etched. After such an etching process is completed, the remaining lower mask material layer (110 of FIG. 17) may be defined as a lower mask pattern 180. That is, after such an etching process is completed, the lower mask pattern 180 may be formed on the upper surface of the stacked structure 100.

For example, the lower mask pattern 180 may include first to seventh lower mask patterns 181 to 187 that are sequentially spaced apart in the first horizontal direction DR1. For example, a first lower mask pattern 181 may be formed below the third upper mask pattern (143 of FIG. 17), a second lower mask pattern 182 may be formed below the fourth upper mask pattern (144 of FIG. 17), a third lower mask pattern 183 may be formed below the first liner pattern (161 of FIG. 17), a fourth lower mask pattern 184 may be formed below the second liner pattern (162 of FIG. 17), a fifth lower mask pattern 185 may be formed below the third liner pattern (163 of FIG. 17), a sixth lower mask pattern 186 may be formed below the fourth liner pattern (164 of FIG. 17), and a seventh lower mask pattern 187 may be formed below the fifth liner pattern (165 of FIG. 17).

For example, each of the first and second lower mask patterns 181 and 182 may be formed on the upper surface of the stacked structure 100 on the first region I of the substrate 10. The third lower mask pattern 183 may be formed on the upper surface of the stacked structure 100 on the boundary line (or boundary area) between the first region I of the substrate 10 and the second region II of the substrate 10. Each of the fourth to seventh lower mask patterns 184 to 187 may be formed on the upper surface of the stacked structure 100 on the second region II of the substrate 10. For example, each of the first to seventh lower mask patterns 181 to 187 may be sequentially spaced apart in the first horizontal direction DR1. For example, each of the first, second, fourth to seventh lower mask patterns 181, 182, and 184 to 187 may extend in the second horizontal direction DR2. For example, the third lower mask pattern 183 may have an angular shape on the plane defined by the first horizontal direction DR1 and the second horizontal direction DR2. For example, on the plane defined by the first horizontal direction DR1 and the second horizontal direction DR2, the shape of the third lower mask pattern 183 may be the same as the shape of the dummy active pattern DF shown in FIG. 1.

For example, while the lower mask pattern 180 is being formed, a portion of the stacked structure 100 and the substrate 10 may be etched. For example, a portion of the stacked structure 100 and the substrate 10 may be etched, by using the lower mask pattern 180 as a mask. After the etching process for a portion of the stacked structure 100 and the substrate 10 is completed, the remaining stacked structure 100 except for the portion that overlaps the lower mask pattern 180 in the vertical direction DR3 may be etched. Further, after the etching process for a portion of the stacked structure 100 and the substrate 10 is completed, each of a dummy active pattern DF and first to sixth active patterns F1 to F6 that protrude in the vertical direction DR3 from the upper surface of the substrate 10 remaining below the remaining stacked structure 100 may be formed.

For example, a first active pattern F1 may be formed below the first lower mask pattern 181, a second active pattern F2 may be formed below the second lower mask pattern 182, a dummy active pattern DF may be formed below the third lower mask pattern 183, a third active pattern F3 may be formed below the fourth lower mask pattern 184, a fourth active pattern F4 may be formed below the fifth lower mask pattern 185, a fifth active pattern F5 may be formed below the sixth lower mask pattern 186, and a sixth active pattern F6 may be formed below the seventh lower mask pattern 187.

For example, each of the first and second active patterns F1 and F2 may be formed on the first region I of the substrate 10. The dummy active pattern DF may be formed on the boundary line (or boundary area) between the first region I of the substrate 10 and the second region II of the substrate 10. Each of the third to sixth active patterns F3 to F6 may be formed on the second region II of the substrate 10. For example, the first and second active patterns F1 and F2, the dummy active pattern DF, and the third to sixth active patterns F3 to F6 may be sequentially spaced apart in the first horizontal direction DR1. For example, each of the first to sixth active patterns F1 to F6 may extend in the second horizontal direction DR2. For example, the dummy active pattern DF may have an annular shape on the plane defined by the first horizontal direction DR1 and the second horizontal direction DR2.

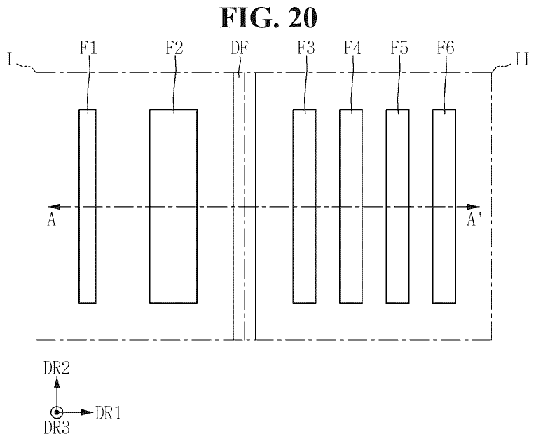

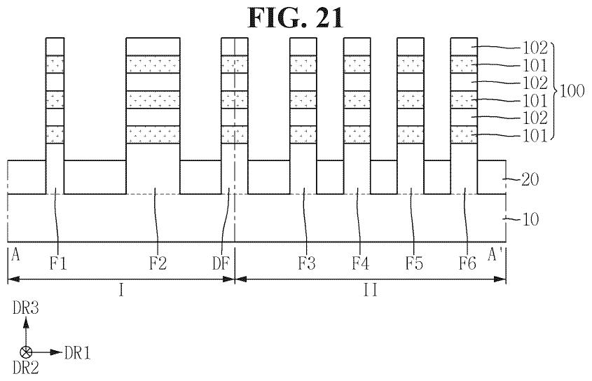

Referring to FIGS. 20 and 21, the lower mask pattern (180 of FIGS. 18 and 19) may be etched. Subsequently, a field insulating layer 20 may be formed on the upper surface of the substrate 10. The field insulating layer 20 may surround side walls of each of the dummy active pattern DF and the first to sixth active patterns F1 to F6. For example, the upper surface of each of the dummy active pattern DF and the first to sixth active patterns F1 to F6 may be formed to be higher than the upper surface of the field insulating layer 20.

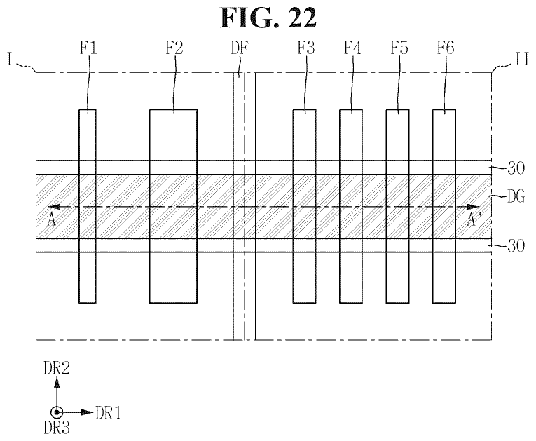

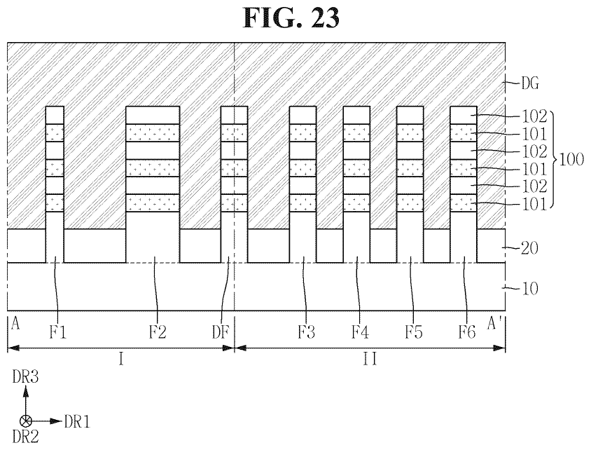

Referring to FIGS. 22 and 23, the dummy gate DG extending in the first horizontal direction DR1 may be formed on each of the field insulating layer 20, the dummy active patterns DF, and the first to sixth active patterns F1 to F6. Next, the gate spacer 30 may be formed on both side walls of the dummy gate DG in the second horizontal direction DR2. The gate spacer 30 may extend in the first horizontal direction DR1.

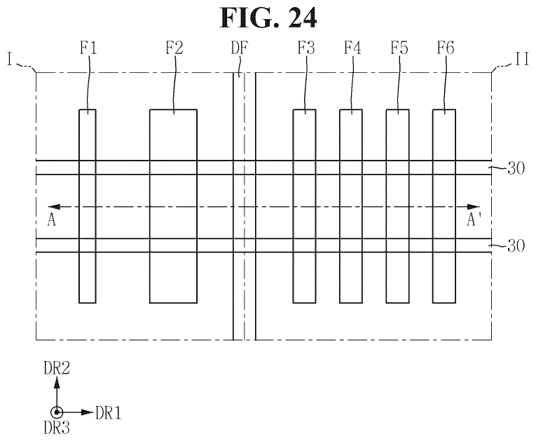

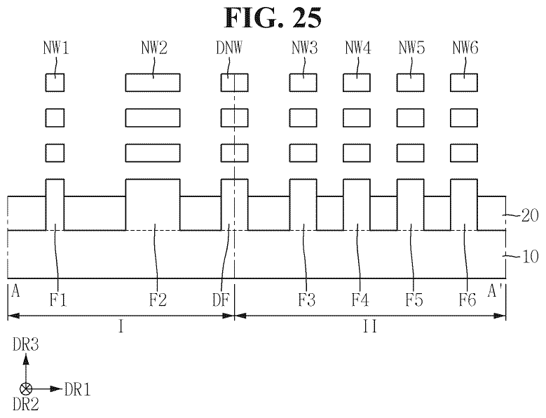

Referring to FIGS. 24 and 25, the dummy gate (DG of FIGS. 22 and 23) and the first semiconductor layer (101 of FIG. 23) may be etched. For example, the remaining second semiconductor layer (102 of FIG. 23) may be defined as a dummy nanosheet DNW and first to sixth plurality of nanosheets NW1 to NW6. For example, the second semiconductor layer (102 of FIG. 23) remaining on the upper surface of the dummy active pattern DF may be defined as the dummy nanosheet DNW. Further, the second semiconductor layer (102 of FIG. 23) remaining on the upper surface of each of the first to sixth active patterns F1 to F6 may be defined as the first to sixth plurality of nanosheets NW1 to NW6.

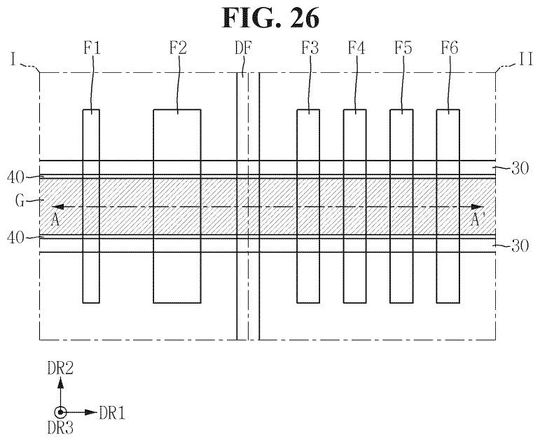

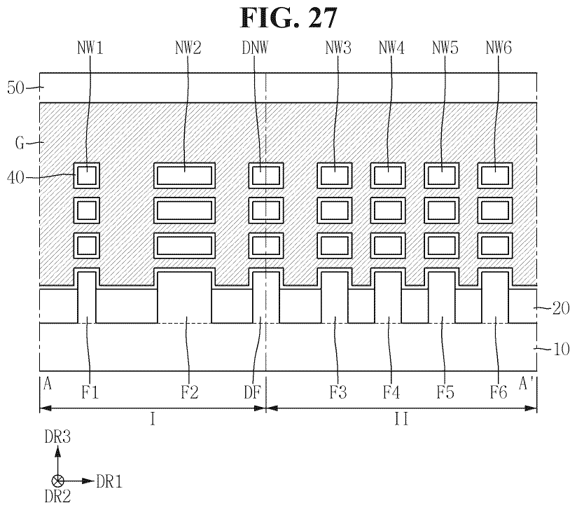

Referring to FIGS. 26 and 27, the gate insulating layer 40 and the gate electrode G may be sequentially formed in the portion from which the dummy gate (DG of FIGS. 22 and 23) is removed. For example, the gate electrode G may surround each of the dummy nanosheet DNW and the first to sixth plurality of nanosheets NW1 to NW6. Subsequently, a capping pattern 50 extending in the first horizontal direction DR1 may be formed on the upper surface of each of the gate spacer 30, the gate insulating layer 40, and the gate electrode G.

Referring to FIGS. 2 and 3, a gate cut GC that penetrates the dummy nanosheet (DNW of FIGS. 26 and 27), the gate electrode (G of FIGS. 26 and 27), and the capping pattern 50 in the vertical direction DR3 may be formed on the upper surface of the dummy active pattern DF. For example, the dummy nanosheet (DNW of FIGS. 26 and 27) may be entirely etched. For example, the gate cut GC may be spaced apart from each of the second plurality of nanosheets NW2 and the third plurality of nanosheets NW3 in the first horizontal direction DR1. For example, a lower surface of the gate cut GC may contact the upper surface of the dummy active pattern DF. For example, an upper surface of the gate cut GC may be formed on the same plane as the upper surface of the capping pattern 50. The gate cut GC may separate the gate electrode (G of FIGS. 26 and 27) into the first gate electrode G1 and the second gate electrode G2. Further, the gate cut GC may separate the capping pattern 50. The semiconductor device shown in FIGS. 2 and 3 may be fabricated through such a fabricating process.

When a liner pattern is formed on the side wall of the third upper mask pattern 143 having a relatively small width in the first horizontal direction DR1 on the first region I of the substrate 10, after the third upper mask pattern 143 is formed in a later process, the liner pattern on the side wall of the third upper mask pattern 143 may be tilted, resulting in a process failure.

In order to solve such a problem, in the method for fabricating the semiconductor device according to one or more embodiments, the liner pattern is not formed on the side walls of the third upper mask pattern 143 having a relatively small width in the first horizontal direction DR1 on the first region I of the substrate 10, and the first active pattern F1 may be formed, by using the third upper mask pattern 143. Therefore, the method for fabricating the semiconductor device according to one or more embodiments of the present disclosure can prevent process defects from occurring.

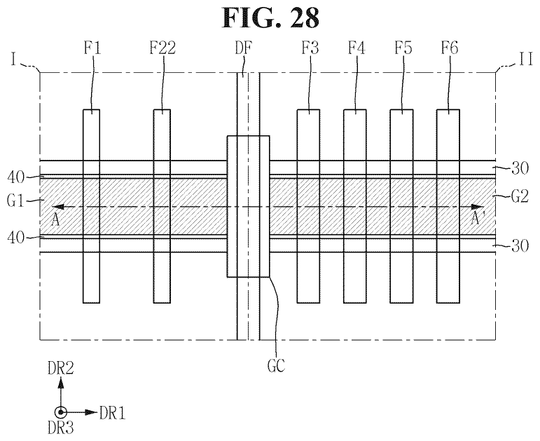

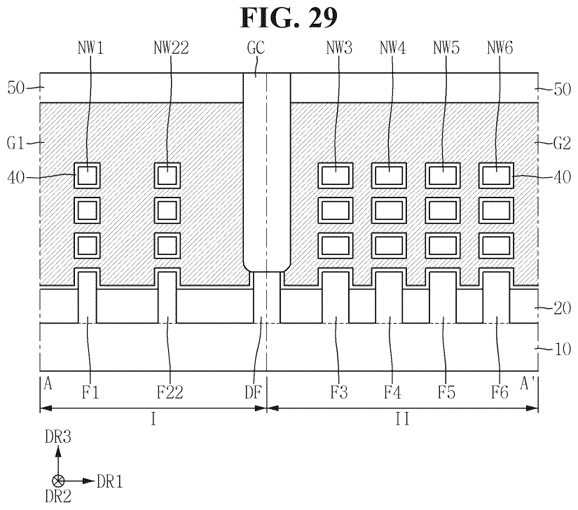

Hereinafter, a semiconductor device according to one or more embodiments will be described with reference to FIGS. 28 and 29. The explanation will focus on the differences from the semiconductor devices shown in FIGS. 1 to 3, and description of same or similar features may be omitted.

FIG. 28 is a diagram illustrating a semiconductor device according to one or more embodiments. FIG. 29 is a cross-sectional view illustrating a semiconductor device according to one or more embodiments.

Referring to FIGS. 28 and 29, in the semiconductor device according to one or more embodiments, a width of the second active pattern F22 in the first horizontal direction DR1 may be equal to a width of the first active pattern F1 in the first horizontal direction DR1.

For example, each of the width of the second active pattern F22 in the first horizontal direction DR1 and the width of the first active pattern F1 in the first horizontal direction DR1 may be smaller than the width of the dummy active pattern DF in the first horizontal direction DR1. Further, each of the width of the second active pattern F22 in the first horizontal direction DR1 and the width of the first active pattern F1 in the first horizontal direction DR1 may be smaller than the width of each of the third to sixth active patterns F3 to F6 in the first horizontal direction DR1.

For example, the width of the second plurality of nanosheets NW22 in the first horizontal direction DR1 may be equal to the width of the first plurality of nanosheets NW1 in the first horizontal direction DR1. For example, each of the width of the first plurality of nanosheets NW1 in the first horizontal direction DR1 and the width of the second plurality of nanosheets NW22 in the first horizontal direction DR1 may be smaller than the width of each of the third to sixth plurality of nanosheets NW3 to NW6 in the first horizontal direction DR1.

Hereinafter, a method for fabricating the semiconductor device according to one or more embodiments will be described with reference to FIGS. 28 to 31. The description focuses on the differences from the method for fabricating the semiconductor device shown in FIGS. 4 to 27, and description of same or similar features may be omitted.

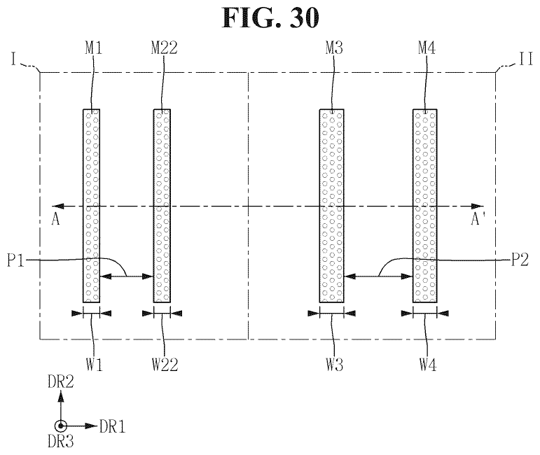

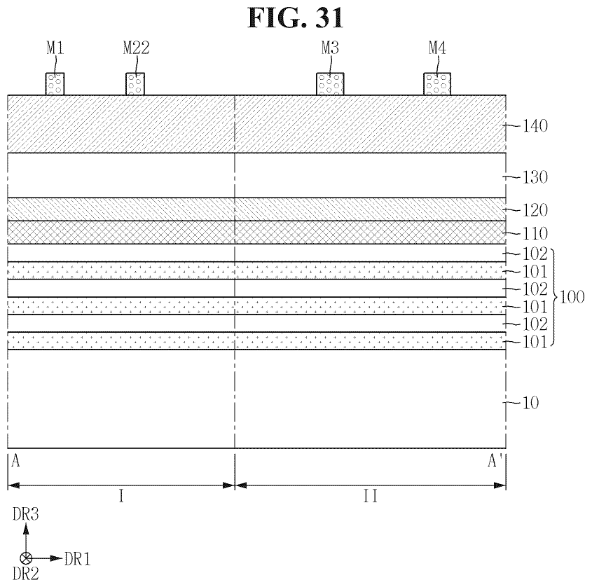

FIGS. 30 and 31 are diagrams illustrating a method of fabricating a semiconductor device according to one or more embodiments.

Referring to FIGS. 30 and 31, after the fabricating processes shown in FIGS. 4 and 5 are performed, the lower mask material layer 110, the first mid mask material layer 120 the second mid mask material layer 130 and the first upper mask material layer 140 may be sequentially formed on the upper surface of the stacked structure 100.

Subsequently, first to fourth mask patterns M1, M22, M3, and M4 may be formed on the upper surface of the first upper mask material layer 140. For example, a width W22 of the second mask pattern M22 in the first horizontal direction DR1 may be equal to a width W1 of the first mask pattern M1 in the first horizontal direction DR1. For example, a width W3 of the third mask pattern M3 in the first horizontal direction DR1 may be equal to a width W4 of the fourth mask pattern M4 in the first horizontal direction DR1. For example, each of the width W1 of the first mask pattern M1 in the first horizontal direction DR1 and the width W22 of the second mask pattern M22 in the first horizontal direction DR1 may be smaller than each of the width W3 of the third mask pattern M3 in the first horizontal direction DR1 and the width W4 of the fourth mask pattern M4 in the first horizontal direction DR1. For example, a pitch P1 in the first horizontal direction DR1 between the first mask pattern M1 and the second mask pattern M22 may be smaller than a pitch P2 in the first horizontal direction DR1 between the third mask pattern M3 and the fourth mask pattern M4.

Referring to FIGS. 28 and 29, after the processes shown in FIGS. 8 to 27 are performed, the gate cut GC that penetrates the dummy nanosheet (DNW of FIGS. 26 and 27), the gate electrode (G of FIGS. 26 and 27) and the capping pattern 50 in the vertical direction DR3 on the upper surface of the dummy active pattern DF may be formed. The semiconductor device shown in FIGS. 28 and 29 may be fabricated through such a fabricating process.

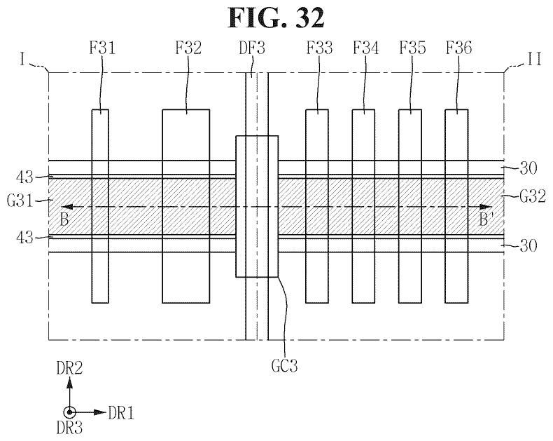

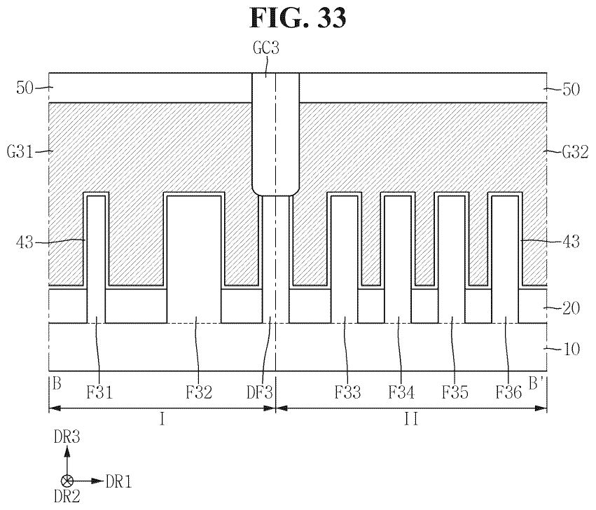

Hereinafter, a semiconductor device according to one or more embodiments will be described with reference to FIGS. 32 and 33. The description will focus on the differences from the semiconductor devices shown in FIGS. 1 to 3, and description of same or similar features may be omitted.

FIG. 32 is a diagram illustrating a semiconductor device according to one or more embodiments. FIG. 33 is a cross-sectional view illustrating a semiconductor device according to one or more embodiments.

Referring to FIGS. 32 and 33, the semiconductor device according to one or more embodiments may have a fin-shaped transistor (FinFET) structure.

For example, each of the first to sixth active patterns F31 to F36 may extend in the second horizontal direction DR2 on the upper surface of the substrate 10. Each of the first to sixth active patterns F1 to F6 may protrude from the upper surface of the substrate 10 in the vertical direction DR3. For example, each of the first and second active patterns F31 and F32 may be disposed on the upper surface of the first region I of the substrate 10. The second active pattern F32 may be spaced apart from the first active pattern F31 in the first horizontal direction DR1. Each of the third to sixth active patterns F33 to F36 may be disposed on the upper surface of the second region II of the substrate 10. The third to sixth active patterns F33 to F36 may be sequentially spaced apart in the first horizontal direction DR1. For example, the dummy active pattern DF3 may be disposed between the second active pattern F32 and the third active pattern F33. The dummy active pattern DF3 may protrude from the upper surface of the substrate 10 in the vertical direction DR3. For example, the dummy active pattern DF3 may be disposed on the boundary line (or boundary area) between the first region I of the substrate 10 and the second region II of the substrate 10.

The first gate electrode G31 may extend in the first horizontal direction DR1 on the field insulating layer 20 and the first and second active patterns F31 and F32. The second gate electrode G32 may extend in the first horizontal direction DR1 on the field insulating layer 20 and the third to sixth active patterns F33 to F36. The second gate electrode G32 may be spaced apart from the first gate electrode G31 in the first horizontal direction DR1. The gate insulating layer 43 may be disposed between each of the first and second gate electrodes G31 and G32 and the field insulating layer 20. The gate insulating layer 43 may be disposed between each of the first and second gate electrodes G31 and G32 and the gate spacer 30. The gate insulating layer 43 may be disposed between the first gate electrode G31 and each of the first and second active patterns F31 and F32. The gate insulating layer 43 may be disposed between the first gate electrode G31 and the dummy active pattern DF3. The gate insulating layer 43 may be disposed between the second gate electrode G32 and each of the third to sixth active patterns F33 to F36. The gate insulating layer 43 may be disposed between the second gate electrode G32 and the dummy active pattern DF3.

A gate cut GC3 may be disposed on the upper surface of the dummy active pattern DF3. The gate cut GC3 may extend in the vertical direction DR3 from the upper surface of the dummy active pattern DF3. The gate cut GC3 may separate the first gate electrode G31 and the second gate electrode G32 in the first horizontal direction DR1. For example, a lower surface of the gate cut GC3 may contact the upper surface of the dummy active pattern DF3. For example, the gate cut GC3 may contact each of the first and second gate electrodes G31 and G32 and the capping pattern 50. For example, the upper surface of the gate cut GC3 may be formed on the same plane as the upper surface of the capping pattern 50.

Hereinafter, a method for fabricating the semiconductor device according to one or more embodiments will be described with reference to FIGS. 32 to 47. The description focuses on the differences from the method for fabricating the semiconductor device shown in FIGS. 4 to 27, and description of same or similar features may be omitted.

FIGS. 34 to 47 are diagrams illustrating a method of fabricating a semiconductor device according to one or more embodiments.

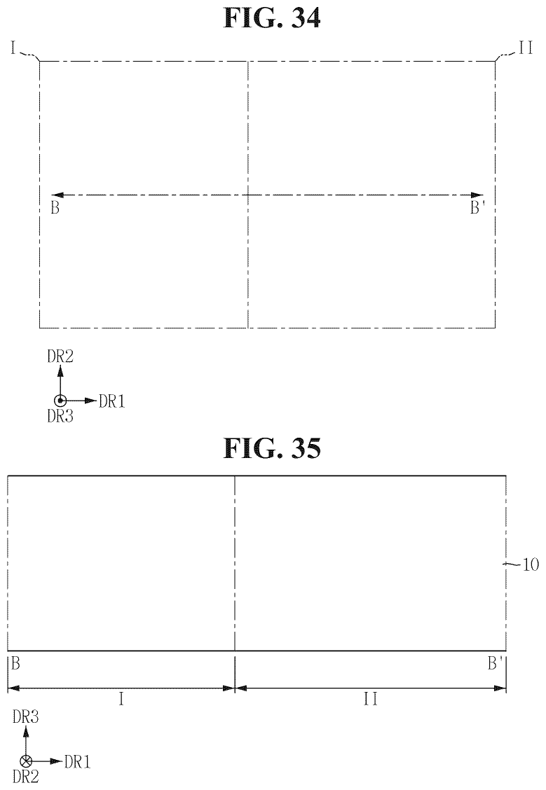

Referring to FIGS. 34 and 35, a substrate 10 including the first region I and the second region II adjacent to the first region I may be provided. For example, as shown in FIG. 1, the first region I may completely surround the second region II, on the plane defined by the first horizontal direction DR1 and the second horizontal direction DR2.

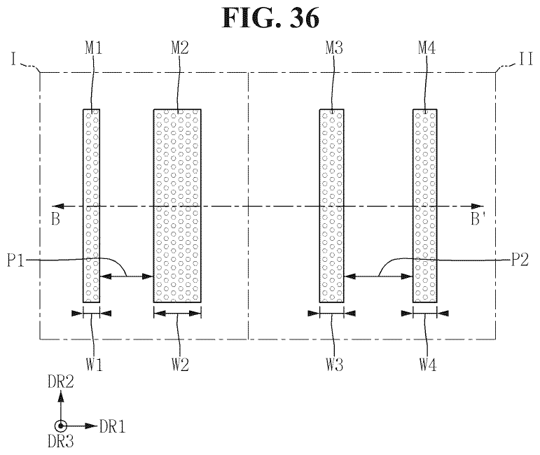

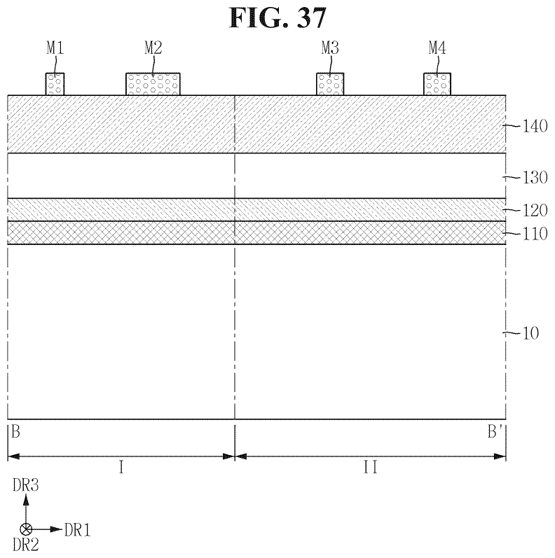

Referring to FIGS. 36 and 37, the lower mask material layer 110, the first mid mask material layer 120, the second mid mask material layer 130, and the first upper mask material layer 140 may be sequentially formed on the upper surface of the substrate 10. Subsequently, first to fourth mask patterns M1 to M4 may be formed on the upper surface of the first upper mask material layer 140. Each of the first to fourth mask patterns M1 to M4 may extend in the second horizontal direction DR2. For example, each of the first and second mask patterns M1 and M2 may be formed on the first region I of the substrate 10. The second mask pattern M2 may be spaced apart from the first mask pattern M1 in the first horizontal direction DR1. For example, each of the third and fourth mask patterns M3 and M4 may be formed on the second region II of the substrate 10. The third mask pattern M3 may be spaced apart from the second mask pattern M2 in the first horizontal direction DR1. The fourth mask pattern M4 may be spaced apart from the third mask pattern M3 in the first horizontal direction DR1.

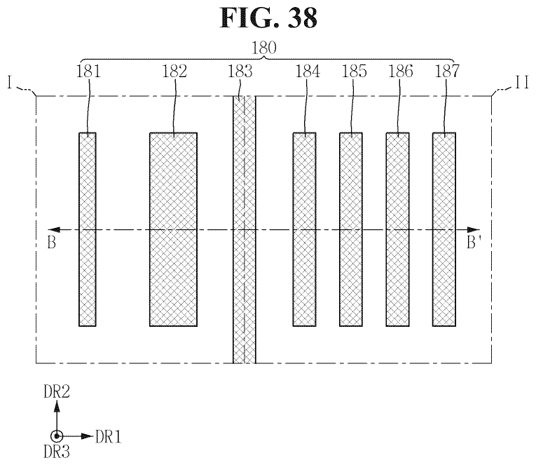

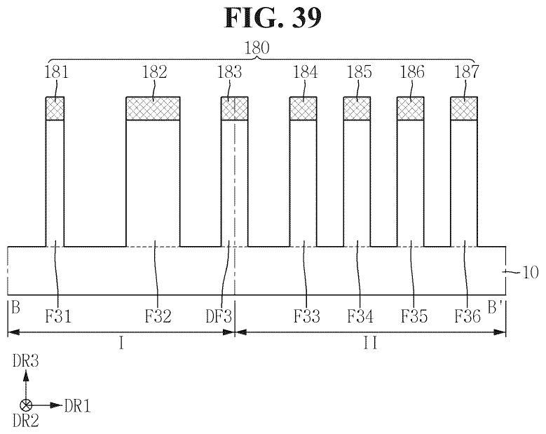

Referring to FIGS. 38 and 39, after the fabricating processes shown in FIGS. 8 to 17 are performed, a portion of the first mid mask material layer (120 of FIG. 17) and the lower mask material layer (110 of FIG. 17) may be etched, by using the third and fourth upper mask patterns (143 and 144 of FIG. 17), the first to fifth liner patterns (161 to 165 of FIG. 4), and the mid mask pattern (135 of FIG. 17) as masks. While such an etching process is being performed, the third and fourth upper mask patterns (143 and 144 of FIG. 17), the first to fifth liner patterns (161 to 165 of FIG. 17), the mid mask pattern (135 of FIG. 17), and the first mid mask material layer (120 of FIG. 17) may be etched. After such an etching process is completed, the remaining lower mask material layer (110 of FIG. 17) may be defined as a lower mask pattern 180. That is, after such an etching process is completed, the lower mask pattern 180 may be formed on the upper surface of the substrate 10.

For example, each of the first and second lower mask patterns 181 and 182 may be formed on the first region I of the substrate 10. The third lower mask pattern 183 may be formed on the boundary line (or boundary area) between the first region I of the substrate 10 and the second region II of the substrate 10. Each of the fourth to seventh lower mask patterns 184 to 187 may be formed on the second region II of the substrate 10. For example, a portion of the substrate 10 may be etched, while the lower mask pattern 180 is being formed. For example, a portion of the substrate 10 may be etched, by using the lower mask pattern 180 as a mask. After the etching process for a portion of the substrate 10 is completed, each of the dummy active patterns DF3 and the first to sixth active patterns F31 to F36 protruding from the upper surface of the remaining substrate 10 in the vertical direction DR3 may be formed below the lower mask pattern 180.

For example, the first active pattern F31 may be formed below the first lower mask pattern 181, the second active pattern F32 may be formed below the second lower mask pattern 182, the dummy active pattern DF3 may be formed below the third lower mask pattern 183, the third active pattern F33 may be formed below the fourth lower mask pattern 184, the fourth active pattern F34 may be formed below the fifth lower mask pattern 185, the fifth active pattern F35 may be formed below the sixth lower mask pattern 186, and the sixth active pattern F36 may be formed below the seventh lower mask pattern 187. For example, each of the first and second active patterns F31 and F32 may be formed on the first region I of the substrate 10. The dummy active pattern DF3 may be formed on the boundary line (or boundary area) between the first region I of the substrate 10 and the second region II of the substrate 10. Each of the third to sixth active patterns F33 to F36 may be formed on the second region II of the substrate 10.

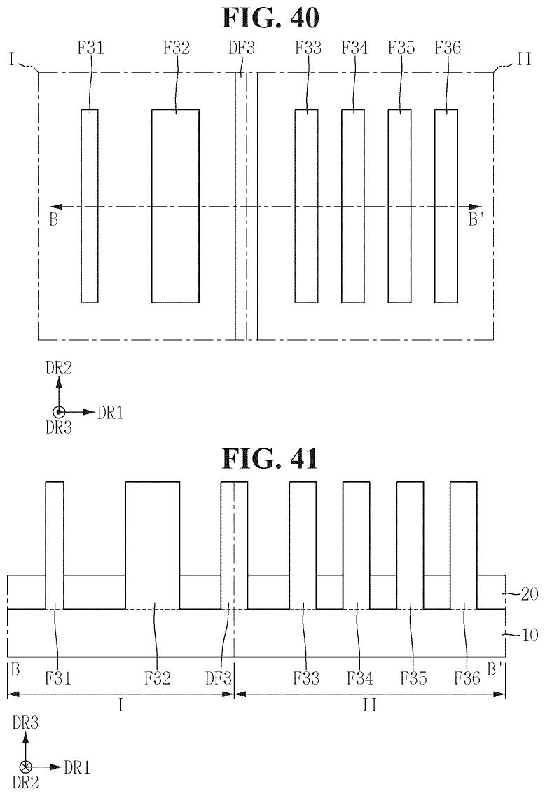

Referring to FIGS. 40 and 41, the lower mask pattern (180 of FIGS. 38 and 39) may be etched. Subsequently, the field insulating layer 20 may be formed on the upper surface of the substrate 10. The field insulating layer 20 may surround the side walls of each of the dummy active pattern DF3 and the first to sixth active patterns F31 to F36. For example, the upper surface of each of the dummy active pattern DF3 and the first to sixth active patterns F31 to F36 may be formed to be higher than the upper surface of the field insulating layer 20.

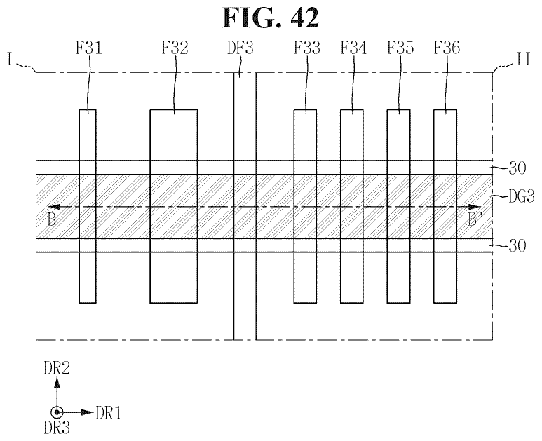

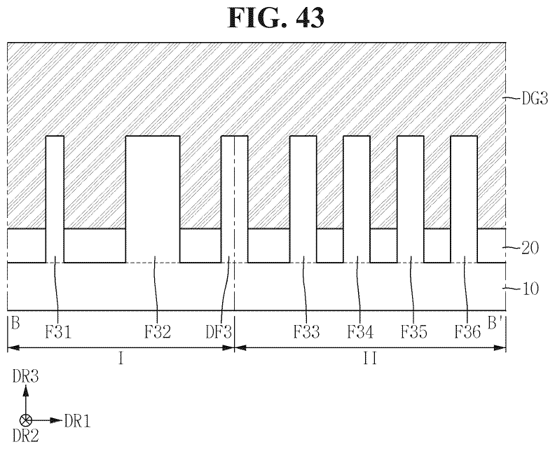

Referring to FIGS. 42 and 43, a dummy gate DG3 extending in the first horizontal direction DR1 may be formed on each of the field insulating layer 20, the dummy active pattern DF3, and the first to sixth active patterns F31 to F36. Subsequently, the gate spacer 30 may be formed on both side walls of the dummy gate DG3 in the second horizontal direction DR2. The gate spacer 30 may extend in the first horizontal direction DR1.

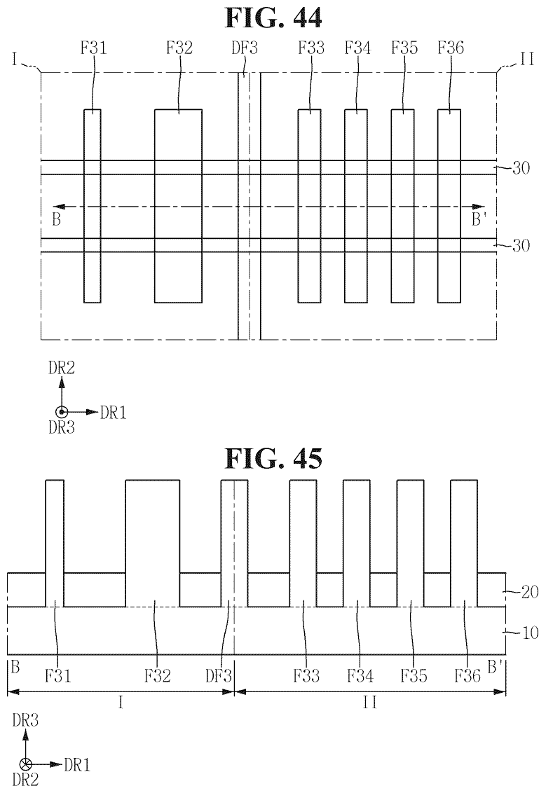

Referring to FIGS. 44 and 45, the dummy gate (DG3 of FIGS. 42 and 43) may be etched.

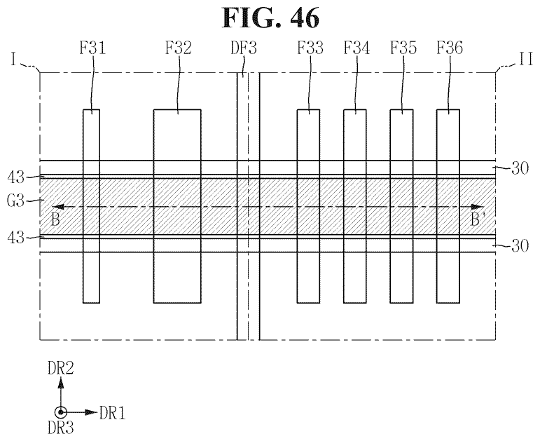

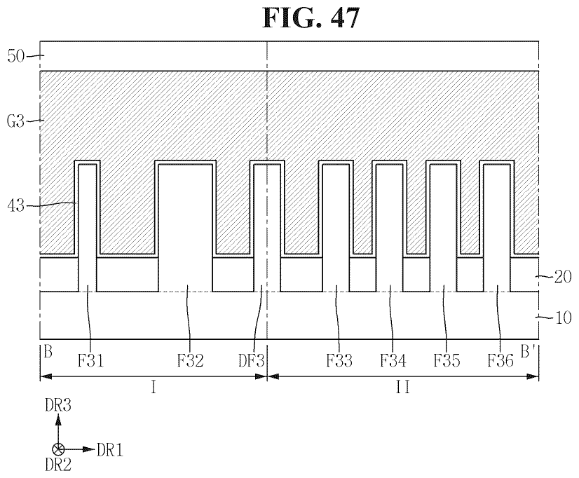

Referring to FIGS. 46 and 47, the gate insulating layer 43 and the gate electrode G3 may be sequentially formed in the portion from which the dummy gate (DG3 of FIGS. 42 and 43) is removed. Subsequently, a capping pattern 50 extending in the first horizontal direction DR1 may be formed on the upper surfaces of each of the gate spacer 30, the gate insulating layer 43, and the gate electrode G3.

Referring to FIGS. 32 and 33, the gate cut GC3 penetrating the gate electrode (G3 of FIGS. 46 and 47) and the capping pattern 50 in the vertical direction DR3 may be formed on the upper surface of the dummy active pattern DF3. For example, the lower surface of the gate cut GC3 may contact the upper surface of the dummy active pattern DF3. For example, the upper surface of the gate cut GC3 may be formed on the same plane as the upper surface of the capping pattern 50. The gate cut GC3 may separate the gate electrode (G2 of FIGS. 46 and 47) into a first gate electrode G31 and a second gate electrode G32. Further, the gate cut GC3 may separate the capping pattern 50. The semiconductor device shown in FIGS. 32 and 33 may be fabricated through such a fabricating process.

In some one or more embodiments, a semiconductor including multi-bridge channel FET (MBCFET™) shown in FIGS. 2 and 3 may be formed in any one of the first region I or the second region II, and a semiconductor device including FinFET shown in FIGS. 32 and 33 may be formed in the other of the first region I and the second region II.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A method of fabricating a semiconductor device, the method comprising:
providing a substrate including a first region and a second region adjacent to the first region;
sequentially forming, on an upper surface of the substrate, a lower mask material layer, a first mid mask material layer, a second mid mask material layer and a first upper mask material layer;
forming a first mask pattern and a second mask pattern spaced apart from each other in a first horizontal direction on an upper surface of the first upper mask material layer on the first region of the substrate;
forming a third mask pattern and a fourth mask pattern spaced apart from each other in the first horizontal direction on the upper surface of the first upper mask material layer on the second region of the substrate;
forming a second upper mask material layer covering the first mask pattern, the second mask pattern, the third mask pattern, and the fourth mask pattern on the upper surface of the first upper mask material layer;
etching the second upper mask material layer on the second region of the substrate;
forming a first upper mask pattern and a second upper mask pattern respectively below the third mask pattern and the fourth mask pattern by etching a portion of the first upper mask material layer on the second region of the substrate;
forming a first liner pattern on a side wall of each of the first upper mask material layer and the second upper mask material layer on a boundary between the first region of the substrate and the second region of the substrate, wherein the first liner pattern does not contact the first mask pattern and the second mask pattern;
forming a first liner layer surrounding the side wall of the first upper mask pattern;
forming a second liner layer surrounding the side wall of the second upper mask pattern;
forming a third upper mask pattern and a fourth upper mask pattern respectively below the first mask pattern and the second mask pattern by etching a portion of the first upper mask material layer;
etching the first upper mask pattern and the second upper mask pattern;
forming a second liner pattern and a third liner pattern spaced apart in the first horizontal direction by etching a portion of the first liner layer;
forming a fourth liner pattern and a fifth liner pattern spaced apart in the first horizontal direction by etching a portion of the second liner layer;
forming a first lower mask pattern, a second lower mask pattern, a third lower mask pattern, a fourth lower mask pattern, a fifth lower mask pattern, a sixth lower mask pattern, and a seventh lower mask pattern sequentially spaced apart in the first horizontal direction and respectively below the third upper mask pattern, the fourth upper mask pattern, the first liner pattern, the second liner pattern, the third liner pattern, the fourth liner pattern, and the fifth liner pattern, by etching the second mid mask material layer, the first mid mask material layer, and the lower mask material layer, the first lower mask pattern and the second lower mask pattern being formed on the first region of the substrate, the third lower mask pattern being formed on the boundary between the first region of the substrate and the second region of the substrate, and the fourth lower mask pattern, the fifth lower mask pattern, the sixth lower mask pattern, and the seventh lower mask pattern being formed on the second region of the substrate; and
forming a first active pattern, a second active pattern, a dummy active pattern, a third active pattern, a fourth active pattern, a fifth active pattern, and a sixth active pattern sequentially spaced apart in the first horizontal direction and respectively below the first lower mask pattern, the second lower mask pattern, the third lower mask pattern, the fourth lower mask pattern, the fifth lower mask pattern, the sixth lower mask pattern, and the seventh lower mask pattern, by etching the substrate.

2. The method of fabricating the semiconductor device of claim 1, wherein the lower mask material layer, the first mid mask material layer, the second mid mask material layer and the first upper mask material layer comprise different materials from each other.

3. The method of fabricating the semiconductor device of claim 1, wherein an upper surface of the first liner pattern is higher than an upper surface of the first liner layer and an upper surface of the second liner layer.

4. The method of fabricating the semiconductor device of claim 1, wherein a width of the dummy active pattern in the first horizontal direction is equal to a width of each of the third active pattern, the fourth active pattern, the fifth active pattern, and the sixth active pattern in the first horizontal direction.

5. The method of fabricating the semiconductor device of claim 1, wherein a pitch in the first horizontal direction between the first mask pattern and the second mask pattern is smaller than a pitch in the first horizontal direction between the third mask pattern and the fourth mask pattern.

6. The method of fabricating the semiconductor device of claim 1, wherein an upper surface of the dummy active pattern is on the same plane as an upper surface of each of the first active pattern, the second active pattern, the third active pattern, the fourth active pattern, the fifth active pattern, and the sixth active pattern.

7. The method of fabricating the semiconductor device of claim 1, wherein the first region completely surrounds the second region on a plane defined by the first horizontal direction and a second horizontal direction different from the first horizontal direction.

8. The method of fabricating the semiconductor device of claim 7, wherein the dummy active pattern is on the boundary between the first region of the substrate and the second region of the substrate, and
wherein the dummy active pattern has an annular shape on the plane defined by the first horizontal direction and the second horizontal direction.

9. The method of fabricating the semiconductor device of claim 1, further comprising, after forming the dummy active pattern and the first active pattern, the second active pattern, the third active pattern, the fourth active pattern, the fifth active pattern, and the sixth active pattern:
forming a dummy gate extending in the first horizontal direction on each of the dummy active pattern, the first active pattern, the second active pattern, the third active pattern, the fourth active pattern, the fifth active pattern, and the sixth active pattern;
etching the dummy gate; and
forming a gate insulating layer and a gate electrode in a portion in which the dummy gate is etched.

10. The method of fabricating the semiconductor device of claim 9, further comprising, after forming the gate insulating layer and the gate electrode:
forming a gate cut extending in a vertical direction on the dummy active pattern, the gate cut contacting the dummy active pattern and separating the gate electrode in the first horizontal direction.

11. The method of fabricating the semiconductor device of claim 1, further comprising, after providing the substrate:
forming a stacked structure in which a first semiconductor layer and a second semiconductor layer are alternately stacked on the upper surface of the substrate.

12. The method of fabricating the semiconductor device of claim 1, wherein a width of the second active pattern in the first horizontal direction is greater than a width of the dummy active pattern in the first horizontal direction.

13. The method of fabricating the semiconductor device of claim 1, wherein a width of the second active pattern in the first horizontal direction is greater than a width of the first active pattern in the first horizontal direction.

14. A method of fabricating a semiconductor device, the method comprising:
providing a substrate including a first region and a second region adjacent to the first region;
forming a stacked structure in which a first semiconductor layer and a second semiconductor layer are alternately stacked on an upper surface of the substrate;
sequentially forming, on an upper surface of the stacked structure, a lower mask material layer, a first mid mask material layer, a second mid mask material layer and a first upper mask material layer on an upper surface of the stacked structure;
forming a first mask pattern and a second mask pattern spaced apart from each other in a first horizontal direction on an upper surface of the first upper mask material layer on the first region of the substrate;
forming a third mask pattern and a fourth mask pattern spaced apart from each other in the first horizontal direction on the upper surface of the first upper mask material layer on the second region of the substrate;
forming a first upper mask pattern and a second upper mask pattern respectively below the third mask pattern and the fourth mask pattern by etching a portion of the first upper mask material layer on the second region of the substrate;
forming a first liner pattern on a side wall of the first upper mask material layer on a boundary between the first region of the substrate and the second region of the substrate, wherein the first liner pattern does not contact the first mask pattern and the second mask pattern;
forming a first liner layer surrounding the side wall of the first upper mask pattern;
forming a second liner layer surrounding the side wall of the second upper mask pattern, wherein an upper surface of the first liner pattern is higher than an upper surface of the first liner layer and an upper surface of the second liner layer;
forming a third upper mask pattern and a fourth upper mask pattern respectively below the first mask pattern and the second mask pattern by etching a portion of the first upper mask material layer on the first region of the substrate;
etching the first upper mask pattern and the second upper mask pattern;
forming a second liner pattern and a third liner pattern spaced apart in the first horizontal direction by etching a portion of the first liner layer;
forming a fourth liner pattern and a fifth liner pattern spaced apart in the first horizontal direction by etching a portion of the second liner layer;
forming a first lower mask pattern, a second lower mask pattern, a third lower mask pattern, a fourth lower mask pattern, a fifth lower mask pattern, a sixth lower mask pattern, and a seventh lower mask pattern sequentially spaced apart in the first horizontal direction and respectively below the third upper mask pattern, the fourth upper mask pattern, the first liner pattern, the second liner pattern, the third liner pattern, the fourth liner pattern, and the fifth liner pattern, by etching the second mid mask material layer, the first mid mask material layer, and the lower mask material layer, the first lower mask pattern and the second lower mask pattern being formed on the first region of the substrate, the third lower mask pattern being formed on the boundary between the first region of the substrate and the second region of the substrate, and the fourth lower mask pattern, the fifth lower mask pattern, the sixth lower mask pattern, and the seventh lower mask pattern being formed on the second region of the substrate; and
forming a first active pattern, a second active pattern, a dummy active pattern, a third active pattern, a fourth active pattern, a fifth active pattern, and a sixth active pattern sequentially spaced apart in the first horizontal direction and respectively below the first lower mask pattern, the second lower mask pattern, the third lower mask pattern, the fourth lower mask pattern, the fifth lower mask pattern, the sixth lower mask pattern, and the seventh lower mask pattern, by etching the substrate.

15. The method of fabricating the semiconductor device of claim 14, wherein an upper surface of the first liner pattern is higher than an upper surface of the first mask pattern and an upper surface of the second mask pattern.

16. The method of fabricating the semiconductor device of claim 14, wherein a width of the dummy active pattern in the first horizontal direction is equal to a width of each of the third active pattern, the fourth active pattern, the fifth active pattern, and the sixth active pattern in the first horizontal direction.

17. The method of fabricating the semiconductor device of claim 14, wherein a pitch in the first horizontal direction between the first mask pattern and the second mask pattern is smaller than a pitch in the first horizontal direction between the third mask pattern and the fourth mask pattern.

18. The method of fabricating the semiconductor device of claim 14, wherein an upper surface of the dummy active pattern is on the same plane as an upper surface of each of the first active pattern, the second active pattern, the third active pattern, the fourth active pattern, the fifth active pattern, and the sixth active pattern.

19. The method of fabricating the semiconductor device of claim 14, wherein a width of the second active pattern in the first horizontal direction is equal to a width of the first active pattern in the first horizontal direction.

20. A method of fabricating a semiconductor device, the method comprising:
providing a substrate including a first region and a second region adjacent to the first region;
forming a stacked structure in which a first semiconductor layer and a second semiconductor layer are alternately stacked on an upper surface of the substrate;
sequentially forming, on an upper surface of the substrate, a lower mask material layer, a first mid mask material layer, a second mid mask material layer and a first upper mask material layer;
forming a first mask pattern and a second mask pattern spaced apart from each other in a first horizontal direction on an upper surface of the first upper mask material layer on the first region of the substrate;
forming a third mask pattern and a fourth mask pattern spaced apart from each other in the first horizontal direction on the upper surface of the first upper mask material layer on the second region of the substrate;
forming a second upper mask material layer covering the first mask pattern, the second mask pattern, the third mask pattern, and the fourth mask pattern on the upper surface of the first upper mask material layer;
etching the second upper mask material layer on the second region of the substrate;
forming a first upper mask pattern and a second upper mask pattern respectively below the third mask pattern and the fourth mask pattern by etching a portion of the first upper mask material layer on the second region of the substrate;
forming a first liner pattern on a side wall of each of the first upper mask material layer and the second upper mask material layer on a boundary between the first region of the substrate and the second region of the substrate, wherein the first liner pattern does not contact the first mask pattern and the second mask pattern;
forming a first liner layer surrounding the side wall of the first upper mask pattern;
forming a second liner layer surrounding the side wall of the second upper mask pattern, wherein an upper surface of the first liner pattern is higher than an upper surface of the first liner layer and an upper surface of the second liner layer;
forming a third upper mask pattern and a fourth upper mask pattern respectively below the first mask pattern and the second mask pattern by etching a portion of the first upper mask material layer on the first region of the substrate;
etching the first upper mask pattern and the second upper mask pattern;
forming a second liner pattern and a third liner pattern spaced apart in the first horizontal direction by etching a portion of the first liner layer;
forming a fourth liner pattern and a fifth liner pattern spaced apart in the first horizontal direction by etching a portion of the second liner layer;
forming a first lower mask pattern, a second lower mask pattern, a third lower mask pattern, a fourth lower mask pattern, a fifth lower mask pattern, a sixth lower mask pattern, and a seventh lower mask pattern sequentially spaced apart in the first horizontal direction respectively below the third upper mask pattern, the fourth upper mask pattern, the first liner pattern, the second liner pattern, the third liner pattern, the fourth liner pattern, and the fifth liner pattern, by etching the second mid mask material layer, the first mid mask material layer, and the lower mask material layer, the first lower mask pattern and the second lower mask pattern being formed on the first region of the substrate, the third lower mask pattern being formed on the boundary between the first region of the substrate and the second region of the substrate, and the fourth lower mask pattern, the fifth lower mask pattern, the sixth lower mask pattern, and the seventh lower mask pattern being formed on the second region of the substrate;
forming a first active pattern, a second active pattern, a dummy active pattern, a third active pattern, a fourth active pattern, a fifth active pattern, and a sixth active pattern sequentially spaced apart in the first horizontal direction and respectively below the first lower mask pattern, the second lower mask pattern, the third lower mask pattern, the fourth lower mask pattern, the fifth lower mask pattern, the sixth lower mask pattern, and the seventh lower mask pattern, by etching the substrate, a width of the dummy active pattern in the first horizontal direction being equal to a width of each of the third active pattern, the fourth active pattern, the fifth active pattern, and the sixth active pattern in the first horizontal direction;
forming a dummy gate extending in the first horizontal direction on the dummy active pattern, the first active pattern, the second active pattern, the third active pattern, the fourth active pattern, the fifth active pattern, and the sixth active pattern;
etching the dummy gate;
forming a gate insulating layer and a gate electrode in a portion in which the dummy gate is etched; and
forming a gate cut extending in a vertical direction on the dummy active pattern, the gate cut contacting the dummy active pattern and separating the gate electrode in the first horizontal direction.
